(19) United States
(12) Patent Application Publication
(10) Pub. No.: US 2008/0110861 A1
(43) Pub. Date: May 15, 2008

(54) Substrate Processing Apparatus and Method

(76) Inventors: Shinji Kajita, Tokyo (JP); Ichiro Katakabe, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/585,482

(22) PCT Filed: Feb. 23, 2005
(86) PCT No.: PCT/JP05/03423

§ 371 Date: Jul. 10, 2006

(30) Foreign Application Priority Data
Feb. 24, 2004 (JP) 2004-047358
May 13, 2004 (JP) 2004-143379
Jun. 28, 2004 (JP) 2004-190474

(51) Int. Cl. B08B 3/04; H01L 21/306

(52) U.S. Cl. 216/83; 156/345.21; 134/26; 134/95.2

(57) ABSTRACT

The substrate processing apparatus has substrate holding mechanisms (14) for holding the substrate (W) under a holding force which is changed according to a rotational speed of the substrate holding mechanisms (14), a substrate rotation mechanism (22) for rotating the substrate holding mechanisms (14) to rotate the substrate (W) held by the substrate holding mechanisms (14), and a treatment liquid supply mechanism (12, 15, 19) for supplying a treatment liquid to a desired portion of the substrate (W) held by the substrate holding mechanisms (14).

### TECHNICAL FIELD

The present invention relates to a substrate processing apparatus and method, and more particularly to a substrate processing apparatus and method for processing a rotating substrate such as a semiconductor wafer while supplying a treatment liquid to the substrate.

### BACKGROUND ART

There has heretofore been known a substrate processing apparatus for supplying a chemical liquid such as a cleaning liquid or an etching liquid, which is hereinafter referred to as a substrate treatment liquid, to front and back surfaces of a substrate (e.g. semiconductor wafer) and an edge surface of the substrate while the substrate is held and rotated by a substrate holding and rotation mechanism. The substrate holding and rotation mechanism of the substrate processing apparatus has a plurality of substrate holding mechanisms for clamping a peripheral portion of the substrate to hold the substrate. However, even if a substrate treatment liquid is supplied to a substrate, which is held and rotated by a substrate holding and rotation mechanism, the substrate treatment liquid is not supplied to portions of the substrate with which the substrate holding mechanisms are brought into contact, i.e., at portions of the substrate which are held by the substrate holding mechanisms. Accordingly, the conventional substrate processing apparatus has been problematic in that those portions of the substrate cannot be processed (cleaned or etched) with the substrate treatment liquid.

From this point of view, there has been developed a substrate processing apparatus having a plurality of substrate holding mechanisms for alternately holding a substrate during processing to prevent portions held by the substrate holding mechanisms from not being processed. Specifically, some of the substrate holding mechanisms hold the substrate while others of the substrate holding mechanisms release the substrate by turns. However, this substrate processing apparatus has a complicated structure and requires troublesome processes for processing a substrate.

Further, there has also been known a substrate processing apparatus for performing a first treatment process including holding a substrate by, for example, attraction of a back surface of the substrate and supplying a substrate treatment liquid to an edge surface of the substrate while rotating the substrate, and a second treatment process including holding the edge surface of the substrate and supplying a substrate treatment liquid to the back surface of the substrate while rotating the substrate.

In the conventional substrate processing apparatus, a sequence of processes of chemical liquid treatment, liquid cleaning, and drying is performed. A chemical liquid attached to the substrate or the substrate holding and rotation mechanism during the chemical liquid treatment may be spattered on and attached to a surface of the substrate, or a mist of the chemical liquid may be attached to a film on the substrate. Thus, the substrate may be contaminated by the chemical liquid. Accordingly, a device for performing a chemical liquid treatment and a device for performing a cleaning process and a drying process should be separately provided to prevent the contamination. Specifically, when a sequence of processes of chemical liquid treatment, pure water cleaning, and drying is performed in a conventional single wafer processing apparatus, a device for processing a substrate and a device for drying the substrate are separated from each other so that a chemical liquid is not spattered on the substrate during the drying process of the substrate, or a mist of the chemical liquid exerts no adverse influence on a film of the substrate during the drying process of the substrate.

However, if a mechanism for processing an edge surface of a substrate and a mechanism for processing a back surface of the substrate are separately provided in a substrate processing apparatus, or if a device for performing a chemical liquid treatment and a device for performing a cleaning process and a drying process are separately provided in a substrate processing apparatus, then a footprint of the apparatus is increased and a throughput of substrate processing is lowered. Accordingly, it is desired to perform the aforementioned processes in a single device to prevent an increased footprint and a lowered throughput due to increased transferring time.

Although there has also been proposed an apparatus for performing a sequence of processes of chemical liquid treatment, pure water cleaning, and drying in a single device, the proposed apparatus has a complicated structure and cannot sufficiently prevent a chemical liquid from being spattered on a substrate when the substrate is being dried. Further, the apparatus cannot sufficiently prevent a mist of the chemical liquid from exerting an adverse influence on a film of the substrate.

### DISCLOSURE OF INVENTION

The present invention has been made in view of the above drawbacks. It is, therefore, a first object of the present invention to provide a substrate processing apparatus and method which can prevent a substrate from not being processed at portions at which a substrate holding mechanism holds the substrate and also prevent contamination from a chemical liquid attached to a substrate during a cleaning process or a drying process.

A second object of the present invention is to provide a substrate processing apparatus and method which can perform a sequence of processes including chemical liquid treatment, pure water cleaning, and drying in a single apparatus and can prevent a substrate from being contaminated by a rebounding treatment liquid, a chemical liquid atmosphere, and a mist of a chemical liquid.

According to a first aspect of the present invention, there is provided a substrate processing apparatus comprising a substrate holding mechanism for holding a substrate under a holding force which is changed according to a rotational speed of the substrate holding mechanism; a substrate rotation mechanism for rotating the substrate holding mechanism to rotate the substrate held by the substrate holding mechanism; and a treatment liquid supply mechanism for supplying a treatment liquid to a desired portion of the substrate held by the substrate holding mechanism.

Thus, the substrate processing apparatus has a substrate holding mechanism for holding a substrate under a holding force which is changed according to a rotational speed of the substrate holding mechanism. Accordingly, a desired holding force can be achieved by adjusting the rotational speed of the substrate holding mechanism. Thus, the substrate can be held under the desired holding force.

The substrate processing apparatus may further comprise a driving device for changing a rotational speed of the substrate holding mechanism relative to a rotational speed of the substrate held by the substrate holding mechanism. In this case, it is possible to change a portion at which the substrate holding mechanism holds the substrate. Accordingly, the substrate is prevented from not being processed at portion at which the substrate holding mechanism holds the substrate. Further, the portion at which the substrate holding mechanism holds the substrate can be changed while the substrate is rotated. Accordingly, the substrate is prevented from not being processed at the holding portion without any additional processes.

According to a second aspect of the present invention, there is provided a substrate processing apparatus comprising a substrate holding mechanism for holding a peripheral portion of a substrate; a base member having the substrate holding mechanism attached thereto, the base member facing at least one surface of the substrate; a rotatable shaft attached to a central portion of the base member; a first liquid supply nozzle for selectively supplying a chemical liquid or a first cleaning liquid to the substrate; a switching device for switching the chemical liquid and the first cleaning liquid to be supplied to the first nozzle; a second liquid supply nozzle for supplying a second cleaning liquid to an inner surface of the substrate holding mechanism and an upper surface of the base member; a gas supply nozzle for supplying a gas to a space between the substrate and the base member; and a nozzle structure including the first liquid supply nozzle, the second liquid supply nozzle, and the gas supply nozzle, the nozzle structure being disposed within the rotatable shaft.

Thus, supply and stop of the chemical liquid, the cleaning liquid, and the gas can be controlled by properly operating these nozzles. Accordingly, a chemical liquid is prevented from being splashed on the substrate during the drying process. Further, a mist of the chemical liquid is prevented from exerting an adverse influence on a film of the substrate.

The first liquid supply nozzle may be configured to clean the first liquid supply nozzle, an outer surface of the nozzle structure, and vicinity thereof with the first cleaning liquid. Thus, the first liquid supply nozzle, the outer surface of the nozzle structure, and the vicinity thereof can be cleaned with the first cleaning liquid. Accordingly, it is possible to prevent a chemical liquid attached to these portions from scattering so as to exert an adverse influence on the film of the substrate.

The substrate processing apparatus may further comprise a first line connected to the first liquid supply nozzle; a second line connected to the second liquid supply nozzle; and a liquid discharge mechanism for discharging a liquid remaining in the first line and the second line. Thus, even if a negative pressure is developed between the substrate and the base member during the drying process, the liquid discharge mechanism can prevent a liquid in the nozzle and the interiors of the lines connected to the nozzle from being ejected from the nozzle. Accordingly, it is possible to prevent a liquid or a mist thereof from being attached to the substrate so as to exert an adverse influence on the film of the substrate.

The substrate processing apparatus may further comprise a purge gas supply line for supplying a purge gas to a gap between the rotatable shaft and the nozzle structure. Thus, a liquid or a mist thereof is prevented from entering the rotatable shaft.

The substrate processing apparatus may further comprise a third liquid supply nozzle for supplying a third cleaning liquid to an outer surface of the substrate holding mechanism. The third liquid supply nozzle can achieve the aforementioned effects more effectively.

The substrate processing apparatus may further comprise a scatter prevention cup disposed outside of the substrate holding mechanism so as to cover the substrate holding mechanism. The scatter prevention cup is movable in a vertical direction. Thus, an inner wall of the scatter prevention cup can be cleaned with a cleaning liquid flowing on an upper surface of the substrate, which has been supplied from the nozzle of the nozzle structure. Accordingly, the substrate is prevented from being contaminated by a cleaning liquid or a mist thereof which has rebounded on the scatter prevention cup.

According to a third aspect of the present invention, there is provided a substrate processing method comprising holding a substrate by a substrate holding mechanism; rotating the substrate holding mechanism by a substrate rotation mechanism to rotate the substrate; and supplying a treatment liquid to a desired portion of the rotating substrate to process the substrate while changing a rotational speed of the substrate holding mechanism and a rotational speed of the substrate relative to each other. The rotational speed of the substrate holding mechanism may be increased or decreased to change the rotational speed of the substrate holding mechanism and the rotational speed of the substrate relative to each other.

Thus, it is possible to change a portion at which the substrate holding mechanism holds the substrate. Accordingly, the substrate is prevented from not being processed at portions at which the substrate holding mechanism holds the substrate. Further, the portion at which the substrate holding mechanism holds the substrate can be changed while the substrate is processed with the treatment liquid. Accordingly, the substrate is prevented from not being processed at the holding portions without any additional processes.

The rotational speed of the substrate holding mechanism may be changed from a first rotational speed to a second rotational speed, and then the rotational speed of the substrate holding mechanism may be returned from the second rotational speed to the first rotational speed. In this case, the rotational speed of the substrate can quickly be made the same as the rotational speed of the substrate holding mechanism.

The supplying the substrate treatment liquid may be stopped simultaneously with or after the increasing or decreasing the rotational speed of the substrate holding mechanism. In this case, larger frictional forces can be produced at the portion at which the substrate holding mechanism holds the substrate. Accordingly, the rotational speed of the substrate can quickly be made the same as the rotational speed of the substrate holding mechanism.

According to a fourth aspect of the present invention, there is provided a substrate processing method comprising holding a substrate by a substrate holding mechanism; rotating the substrate holding mechanism by a substrate rotation mechanism to rotate the substrate, supplying a treatment liquid to the rotating substrate to process the substrate; rotating the substrate at a first high rotational speed after the supplying the treatment liquid; supplying a cleaning liquid to at least one surface of the substrate rotated at the first high rotational speed to clean the treatment liquid attached to the substrate; and removing a chemical liquid attached to at least one of the substrate holding mechanism and the substrate rotation mechanism in a state such that the at least one surface of the substrate is covered with the cleaning liquid. The first high rotational speed may be in a range of 1000 to 3000 rpm.

In this case, even if a chemical liquid blown onto the substrate from the substrate holding mechanism, the chemical liquid is prevented from being attached to the substrate. Further, when a chemical liquid scatters from the substrate holding mechanism and rebounds, the chemical liquid is prevented from becoming a mist which would have an adverse influence on the front and back surfaces of the substrate.

The substrate may be rotated at a second high rotational speed to remove the cleaning liquid and dry the substrate. In this case, the substrate may be rotated at a high rotational speed substantially equal to the first high rotational speed for a desired period of time. Thus, since the substrate holding mechanism is rotated at a high rotational speed in the cleaning process, a chemical liquid attached to the substrate holding mechanism can be reliably removed. Additionally, since a chemical liquid attached to the substrate holding mechanism in the cleaning process can be reliably removed, the chemical liquid is prevented from being attached to the substrate in the drying process to cause contamination of the substrate.

According to a fifth aspect of the present invention, there is provided a substrate processing method comprising holding a substrate by a substrate holding mechanism; rotating the substrate holding mechanism by a substrate rotation mechanism to rotate the substrate; supplying a treatment liquid to the rotating substrate to process the substrate; and supplying a cleaning liquid to the rotating substrate to clean the substrate holding mechanism. The substrate holding mechanism may be rotated at a rotational speed lower than 300 rpm during the supplying the cleaning liquid. Thus, when the substrate is cleaned, a chemical liquid attached to the substrate holding mechanism can be cleaned.

According to a sixth aspect of the present invention, there is provided a substrate processing method comprising holding a substrate by a substrate holding mechanism; rotating the substrate holding mechanism by a substrate rotation mechanism to rotate the substrate; supplying a treatment liquid to the rotating substrate to process the substrate; rotating the substrate at a first high rotational speed after supplying the treatment liquid; supplying a cleaning liquid to at least one surface of the substrate rotated at the first high rotational speed to clean the treatment liquid attached to the substrate; removing a chemical liquid attached to at least one of the substrate holding mechanism and the substrate rotation mechanism in a state such that the at least one surface of the substrate is covered with the cleaning liquid; supplying a cleaning liquid to the rotating substrate to clean the substrate holding mechanism; and rotating the substrate at a second rotational speed substantially equal to the first high rotational speed for a desired period of time to remove the cleaning liquid and dry the substrate. The cleaning liquid may comprise pure water, deaerated water, or gas dissolved water.

Thus, since the substrate holding mechanism is rotated at a high rotational speed, a chemical liquid attached to the substrate holding mechanism can reliably be removed in the cleaning process of the substrate. Even if a chemical liquid is blown onto the substrate from the substrate holding mechanism, the chemical liquid is prevented from being attached to the substrate. Further, when a chemical liquid scatters from the substrate holding mechanism and rebounds, the chemical liquid is prevented from becoming a mist which would have an adverse influence on the front and back surfaces of the substrate. Further a chemical liquid attached to the substrate holding mechanism can reliably be removed in the cleaning process of the substrate holding mechanism. Additionally, chemical liquids attached to the substrate holding mechanism can reliably be removed in the cleaning process of the substrate and the cleaning process of the substrate holding mechanism. Accordingly, the chemical liquid is prevented from being attached to the substrate in the drying process. Thus, contamination of the substrate can be prevented.

The treatment liquid may be supplied to a peripheral portion of the substrate to remove a film formed on the peripheral portion of the substrate. The film to be removed may comprise a film containing one of Cu, Co, Co alloy, Ta, Ta—N, W, W-N, Ti, Ti—N, Ni, Ru, P, B, and Mo, or a film having a plurality of layers each containing one of Cu, Co, Co alloy, Ta, Ta—N, W, W-N, Ti, Ti—N, Ni, Ru, P, B, and Mo. In this case, during processing the film of the substrate, it is possible to move a portion at which the substrate holding holds the substrate. Accordingly, the film formed at the peripheral portion of the substrate can be removed without any portions remaining unprocessed. Further, since it is possible to move the holding portion of the substrate during removing the film, the substrate is prevented from not being processed at the holding portion without any additional processes.

According to a seventh aspect of the present invention, there is provided a substrate processing method comprising holding a substrate by a substrate holding mechanism; rotating the substrate holding mechanism by a substrate rotation mechanism to rotate the substrate; supplying a treatment liquid to the rotating substrate to process the substrate; supplying a chemical liquid from a first liquid supply nozzle to the substrate; switching a liquid to be supplied from the first liquid supply nozzle into a cleaning liquid to supply the cleaning liquid to the substrate, supplying a cleaning liquid to the first liquid supply nozzle and vicinity of the first liquid supply nozzle to clean the first liquid supply nozzle and vicinity of the first liquid supply nozzle; and rotating the substrate holding mechanism to remove a liquid attached to the substrate and dry the substrate.

Thus, a chemical liquid is prevented from being splashed on the substrate during the drying process. Further, a mist of the chemical liquid is prevented from exerting an adverse influence on a film of the substrate. Since the first liquid supply nozzle and the vicinity of the first liquid supply nozzle can be cleaned, no adverse influence is exerted on the film of the substrate by a liquid remaining in the first liquid supply nozzle and the vicinity of the first liquid supply nozzle or a mist thereof.

The supplying the cleaning liquid may be stopped, and a liquid remaining in the first liquid supply nozzle and a line connected to the first liquid supply nozzle may be discharged after the stopping and before the drying the substrate. Thus, even if a negative pressure is developed between the substrate and the base member during the drying process, the liquid discharge mechanism can prevent a liquid in the nozzle and the interiors of the lines connected to the nozzle from being ejected from the nozzle. Accordingly, it is possible to prevent a liquid or a mist thereof from being attached to the substrate so as to exert an adverse influence on the film of the substrate.

Further, a cleaning liquid may be supplied from a second liquid supply nozzle, before the drying the substrate, to clean an inner surface of the substrate holding mechanism and an upper surface of a base member having the substrate holding mechanism attached thereon. Thus, since the inner surface of the substrate holding mechanism and the upper surface of the base member can be cleaned, it is possible to more effectively prevent an adverse influence on the film of the substrate.

A gas may be supplied from a gas supply nozzle to a space between the substrate and a base member having the substrate holding mechanism attached thereon during the drying the substrate. Thus, since a mist or the like cannot enter the space, the mist is prevented from exerting an adverse influence. The gas can blow a liquid at a central portion of a lower surface of the substrate. Accordingly, the gas can help to dry the central portion of the lower surface of the substrate, from which a liquid is unlikely to be blown off by spin-drying.

The gas may be supplied from the gas supply nozzle to the space between the substrate and the base member during the cleaning the first liquid supply nozzle and the vicinity thereof. Since the gas prevents a liquid from entering the space, the gas can effectively be supplied during the drying process.

The above and other objects, features, and advantages of the present invention will be apparent from the following description when taken in conjunction with the accompanying drawings which illustrate preferred embodiments of the present invention by way of example.

### BRIEF DESCRIPTION OF DRAWINGS

FIG. 1 is a schematic view showing a substrate processing apparatus according to a first embodiment of the present invention;

FIG. 2A is a partial plan view showing a substrate holding mechanism in the substrate processing apparatus shown in FIG. 1;

FIG. 2B is a schematic cross-sectional view taken along line A-A of FIG. 2A;

FIGS. 3A and 3B are cross-sectional views explanatory of operation of the substrate holding mechanism in FIG. 2B;

FIGS. 4A through 4C are graphs showing examples of changes in rotational speed of the substrate holding mechanism of the substrate processing apparatus shown in FIG. 1;

FIGS. 5A and 5B are graphs showing examples of changes in rotational speed of the substrate holding mechanism of the substrate processing apparatus shown in FIG. 1;

FIG. 6 is a flowchart showing an example of treatment process in the substrate processing apparatus shown in FIG. 1;

FIG. 7 is a schematic view showing operation of the substrate processing apparatus shown in FIG. 1;

FIG. 8 is a schematic view showing operation of the substrate processing apparatus shown in FIG. 1;

FIG. 9 is a schematic view showing operation of the substrate processing apparatus shown in FIG. 1;

FIG. 10 is flowchart showing another example of treatment process in the substrate processing apparatus shown in FIG. 1;

FIG. 11 is a schematic side view showing a substrate processing apparatus according to a second embodiment of the present invention;

FIG. 12 is a plan view showing substrate holding chucks and a chuck holding base in the substrate processing apparatus shown in FIG. 11;

FIG. 13 is a schematic view showing operation of the substrate processing apparatus shown in FIG. 11;

FIG. 14 is a schematic view showing operation of the substrate processing apparatus shown in FIG. 11;

FIG. 15 is a plan view showing a Cu plating apparatus incorporating a substrate processing apparatus according to the present invention; and

FIG. 16 is a plan view showing an electroless plating apparatus incorporating a substrate processing apparatus according to the present invention.

### BEST MODE FOR CARRYING OUT THE INVENTION

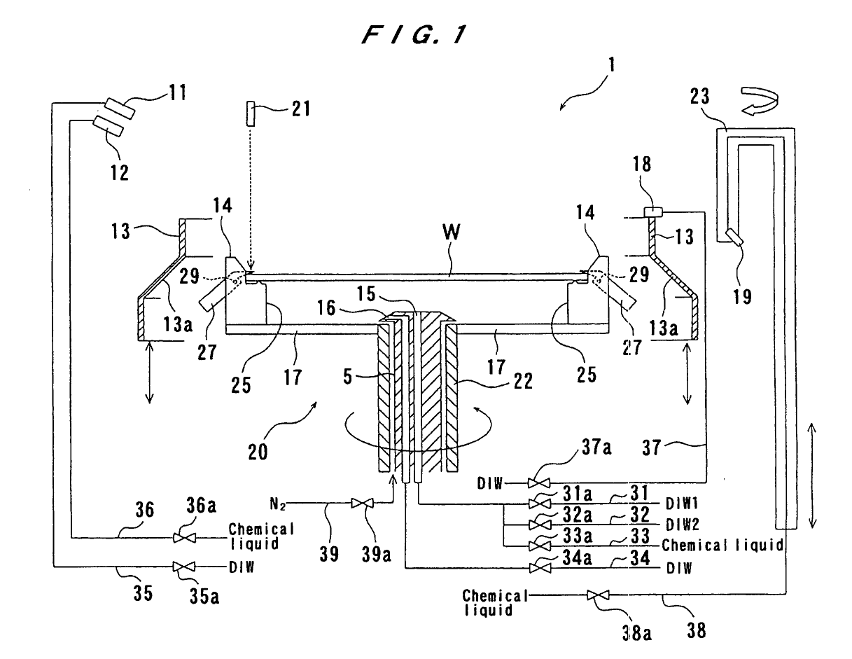

Embodiments of a substrate processing apparatus according to the present invention will be described below with reference to FIGS. 1 through 16. In FIGS. 1 through 16, like or corresponding parts are denoted by like or corresponding reference numerals and will not be described repetitively.

FIG. 1 shows a schematic arrangement of a substrate processing apparatus 1 according to a first embodiment of the present invention. As shown in FIG. 1, the substrate processing apparatus 1 has a substrate holding and rotation mechanism 20 including a rotatable shaft 22 as a substrate rotation mechanism for rotating a substrate W such as a semiconductor wafer to be processed, a plurality of base members 17 extending radially from an upper end of the rotatable shaft 22 in horizontal outward directions, and substrate holding mechanisms 14 provided on tip ends of the base members 17. There are provided a plurality of sets (at least three sets) of the base members 17 and the substrate holding mechanisms 14. The substrate W is held on a central portion of the plurality substrate holding mechanisms 14.

The substrate processing apparatus 1 has a driving device coupled to the rotatable shaft 22. The substrate holding and rotation mechanism 20 rotates the substrate W about the rotatable shaft 22 while the substrate holding mechanisms 14 hold the substrate W. The driving device accelerates or decelerates the substrate holding and rotation mechanism 20 at a desired acceleration or deceleration so as to rotate the rotatable shaft 22 at a desired rotational speed. For example, there may be used a Si substrate having a thermal oxide film deposited on the Si substrate, and a Ta—N film, a Cu sputtering film, and a Cu plating film deposited on the thermal oxide film. The thermal oxide film may have a thickness of about 1000 Å. The Ta—N film may have a thickness of about 300 Å. The Cu sputtering film may have a thickness of about 1500 Å. The Cu plating film may have a thickness of about 10000 Å. The thermal oxide films are deposited on front and back surfaces of the Si substrate. The other films are deposited only on the front surface of the Si substrate.

The substrate processing apparatus 1 includes a nozzle structure 5 disposed near a central portion of the substrate holding and rotation mechanism 20. The nozzle structure 5 has a nozzle 15 opened to the back surface of the substrate W held by the substrate holding mechanisms 14, and a nozzle 16 opened substantially in a horizontal direction. The nozzle structure 5 is formed separately from the rotatable shaft 22 and is not thus rotated together with the rotatable shaft 22. The nozzle 15 supplies a substrate treatment liquid to the back surface of the substrate W. The nozzle 16 jets a substrate treatment liquid substantially in a sectorial shape so as to supply the substrate treatment liquid to upper surfaces of the base members 17 and inner surfaces of the substrate holding mechanisms 14 (at the rotatable shaft 22 side).

Further, the nozzle 15 is connected to chemical liquid lines 31 and 32 for supplying substrate cleaning liquids and a chemical liquid line 33 for supplying another chemical liquid. Types of substrate treatment liquids to be supplied from the nozzle 15 can be switched by opening or closing valves 31a, 32a, and 33a provided on the chemical liquid lines 31, 32, and 33. Thus, the valves 31a, 32a, and 33a serve as a switching device for switching substrate treatment liquids to be supplied to the nozzle 15. The nozzle 16 is connected to a liquid supply line 34 for supplying a substrate cleaning liquid. The liquid supply line 34 has a valve 34a provided thereon. Although DIW (pure water) or gas dissolved water is generally used as the substrate cleaning liquid, other chemical liquids can be used for the cleaning.

The substrate processing apparatus 1 also includes a nozzle 18 disposed outside of the substrate holding and rotation mechanism 20 for cleaning the substrate holding and rotation mechanism 20 with a cleaning liquid. The nozzle 18 jets a cleaning liquid substantially in a sectorial shape from a tip end of the nozzle 18 to outer surfaces of the substrate holding mechanisms 14 (at an opposite side to the rotatable shaft 22) and outer surfaces of the base members 17 so as to clean these surfaces. The nozzle 18 is connected to a cleaning liquid line 37, which has a valve 37a provided thereon.

The substrate processing apparatus 1 further includes nozzles 11 and 12 disposed above the substrate holding and rotation mechanism 20. The nozzle 11 supplies a cleaning liquid to the front surface of the substrate W, whereas the nozzle 12 supplies a chemical liquid to the front surface of the substrate W. The nozzle 11 is connected to a liquid supply line 35, which has a valve 35a provided thereon. The nozzle 12 is connected to a liquid supply line 36, which has a valve 36a provided thereon. Flow rates of the cleaning liquid and the chemical liquid supplied from the nozzles 11 and 12, respectively, can be controlled so as to have several levels by adjusting openings of the valves 35a and 36a.

The substrate processing apparatus 1 has a scatter prevention cup 13 for preventing substrate treatment liquids supplied to the substrate W from scattering. The scatter prevention cup 13 is disposed so as to surround the substrate holding and rotation mechanism 20. The scatter prevention cup 13 is movable in a vertical direction. When the scatter prevention cup 13 is located at a position shown in FIG. 1, i.e., substantially at the same height as the substrate holding mechanisms 14, the scatter prevention cup 13 receives substrate treatment liquids scattering from the substrate holding and rotation mechanism 20 and the substrate W mainly by an inclined portion 13a.

As shown in FIG. 1, the substrate processing apparatus 1 includes an arm section 23 disposed outside of the scatter prevention cup 13. The arm section 23 is configured to be swingable and vertically movable. The arm section 23 has an edge nozzle 19 provided at a tip end of the arm section 23 for supplying a substrate treatment liquid to the substrate W. The arm section 23 can move the edge nozzle 19 to a desired position. For example, the arm section 23 can move the edge nozzle 19 to a position above the substrate W so as to supply a substrate treatment liquid to a desired area of the substrate W. Alternatively, the arm section 23 can retract the edge nozzle 19 to a position outside of the scatter prevention cup 13. The edge nozzle 19 is connected to a liquid supply line 38, which has a valve 38a provided thereon.

The rotatable shaft 22 is connected to a N₂ gas supply line 39, which has a N₂ valve 39a provided thereon. During processing the substrate W, the N₂ valve 39a is opened to supply a N₂ gas from the N₂ gas supply line 39. Accordingly, substrate treatment liquids such as a cleaning liquid and a chemical liquid are prevented from entering the interior of the rotatable shaft 22 during processing the substrate W.

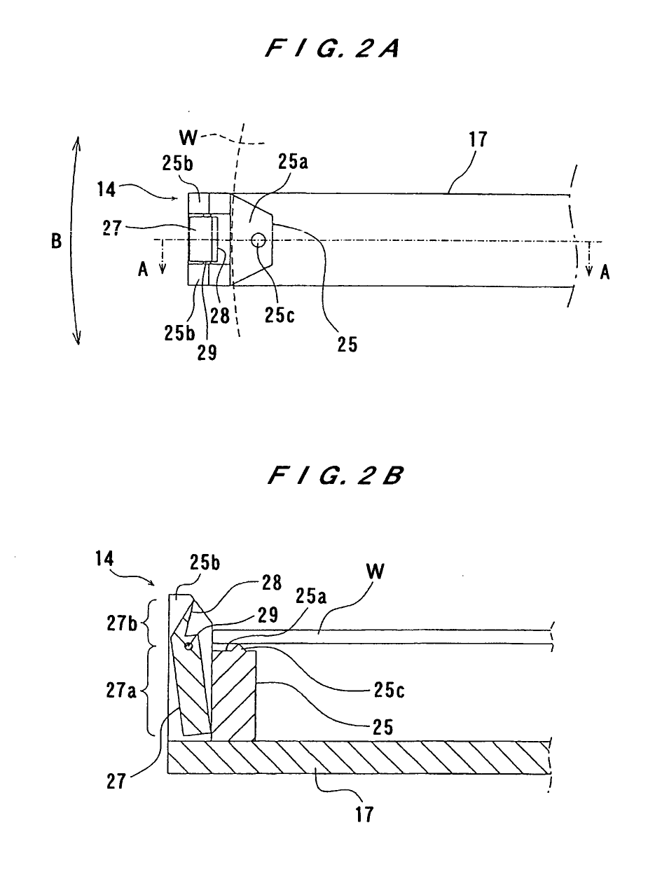

The substrate holding mechanisms 14 will be described in detail below. FIGS. 2A and 2B are partial enlarged views showing one of the substrate holding mechanisms 14. FIG. 2A is a plan view of the substrate holding mechanism 14, and FIG. 2B is a schematic cross-sectional view taken along line A-A of FIG. 2A. As shown in FIGS. 2A and 2B, the substrate holding mechanism 14 includes a body 25 having a horizontal surface 25a formed on the body 25 at the rotatable shaft 22 side, and a projection 25c provided on the horizontal surface 25a, on which the substrate W is placed. The body 25 also has a pair of side plates 25b and 25b spaced at a predetermined distance so as to face each other, and a shaft 29 horizontally extending between the side plates 25b and 25b. The substrate holding mechanism 14 has a pawl 27 through which the shaft 29 extends. The pawl 27 is rotatable about the shaft 29.

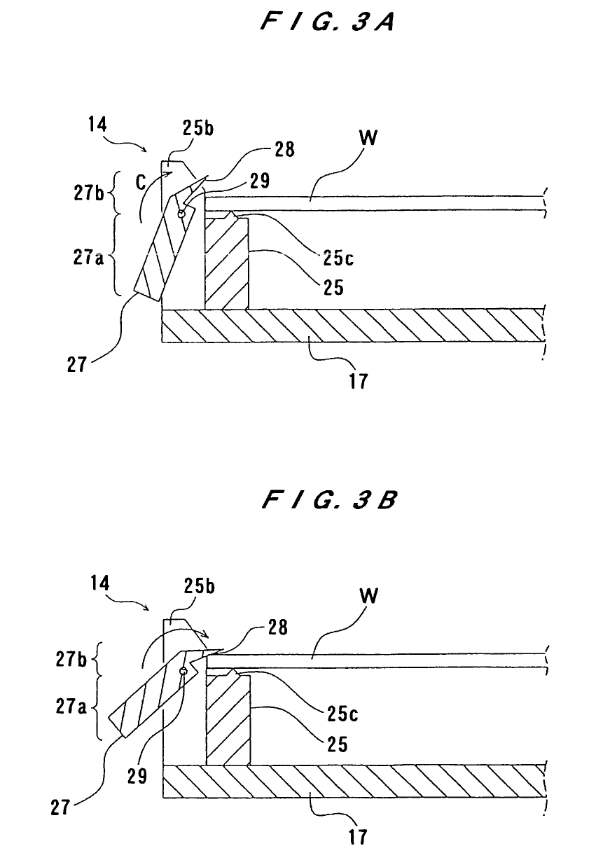

The shaft 29 extends through the pawl 27 at a position such that the mass of a lower portion 27a of the pawl 27 which is located below the shaft 29 is greater than that of an upper portion 27b of the pawl 27 which is located above the shaft 29. When the substrate holding and rotation mechanism 20 rotates, the substrate holding mechanism 14 is rotated in a direction indicated by arrow B in FIG. 2A. If the rotational speed of the substrate holding mechanism 14 is increased, a centrifugal force is applied to the pawl 27 so as to rotate the pawl 27 about the shaft 29 in a direction indicated by arrow C in FIG. 3A. Specifically, the pawl 27 is rotated so as to bring a presser 28, which is provided on the upper portion 27b of the pawl 27, into contact with an upper surface of the substrate W. Then, as shown in FIG. 3B, the presser 28 presses the substrate W placed on the projection 25c from above the projection 25c and holds the substrate W.

A force for the presser 28 to press the substrate W, i.e., a holding force for the substrate holding mechanism 14 to hold the substrate W, depends on a rotational speed of the substrate holding and rotation mechanism 20. As the substrate holding and rotation mechanism 20 has a higher rotational speed, the substrate holding mechanism 14 holds the substrate under a greater holding force. Accordingly, when the rotational speed of the substrate holding and rotation mechanism 20 is increased, frictional forces, such as a static frictional force, a maximum frictional force, or a kinetic frictional force, produced at portions at which the pressers 28 and the projections 25c of the substrate holding mechanisms 14 are brought into contact with the substrate W are increased.

Next, there will be described operation of changing holding portions of the substrate W held by the substrate holding mechanisms 14. First, as shown in FIGS. 2A and 2B, a substrate W is placed on the projections 25c of the substrate holding mechanisms 14. At that time, the substrate holding mechanisms 14 are rotated. When the rotational speed of the substrate holding mechanisms 14 is increased, the pawls 27 are gradually rotated in the direction indicated by arrow C in FIG. 3A. Then, as shown in FIG. 3B, the pressers 28 press the substrate W from above the substrate W so that the substrate W is held by the pressers 28 and the projections 25c. At that time, the substrate W held by the substrate holding mechanisms 14 is rotated integrally with the substrate holding mechanisms 14. When the rotational speed of the substrate holding mechanisms 14 is further increased, holding forces for the substrate holding mechanisms 14 to hold the substrate W are increased. When the rotational speed of the substrate holding mechanisms 14 is increased until desired holding forces are produced, the rotational speed of the substrate holding mechanisms 14 is maintained at a constant value, which is hereinafter referred to as an initial rotational speed.

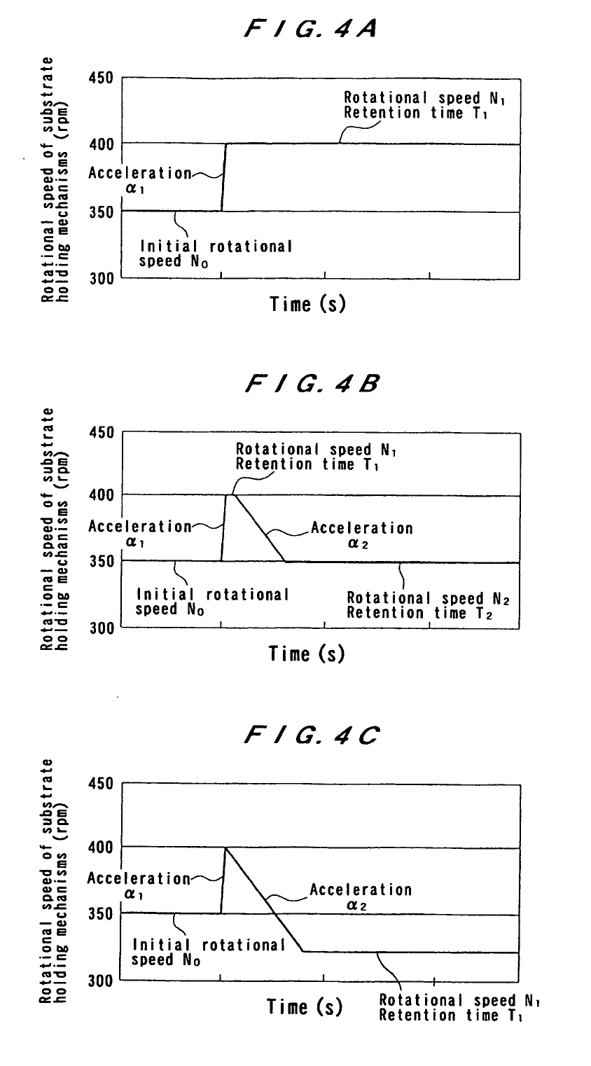

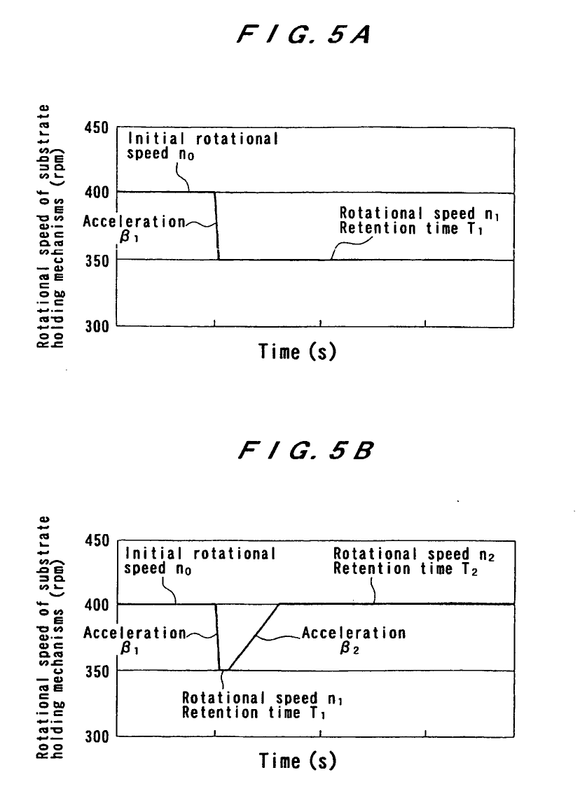

FIGS. 4A through 4C, 5A, and 5B show some examples of changes in rotational speed of the substrate holding mechanisms 14 from the initial rotational speed. As shown in FIG. 4A, the rotational speed of the substrate holding mechanisms 14, which are rotated at the initial rotational speed N₀ (350 rpm in FIG. 4A), is increased at an acceleration α₁ (1000 rpm/s in FIG. 4A) such that inertia forces produced on the substrate W are greater than static frictional forces (maximum frictional forces) produced at portions at which the pressers 28 and the projections 25c are brought into contact with the substrate W. Thus, the rotational speed of the substrate holding mechanisms 14 is increased to a rotational speed N₁ (400 rpm in FIG. 4A). As a result, sliding is produced at the portions at which the pressers 28 and the projections 25c are brought into contact with the substrate W to move holding portions of the substrate W which are held by the pressers 28. At that time, a relative rotational speed of the substrate W to the substrate holding mechanisms 14 is changed so that the substrate W begins to move relative to the substrate holding mechanisms 14. Then, the relative rotational speed of the substrate W to the substrate holding mechanisms 14 is gradually decreased by kinetic frictional forces produced at portions at which the pressers 28 and the projections 25c are brought into contact with the substrate W. After a predetermined period of time, the rotational speed of the substrate W and the rotational speed of the substrate holding mechanisms 14 become the same value N₁. Then, the substrate W is rotated integrally with the substrate holding mechanisms 14 while the substrate W is held at portions other than the initial holding portions.

In another example as shown in FIG. 5A, the rotational speed of the substrate holding mechanisms 14, which are rotated at an initial rotational speed n₀ (400 rpm in FIG. 5A), is decreased at an acceleration β₁ (−1000 rpm/s in FIG. 5A) such that inertia forces produced on the substrate W are greater than static frictional forces (maximum frictional forces) produced at portions at which the pressers 28 and the projections 25c are brought into contact with the substrate W. Thus, the rotational speed of the substrate holding mechanisms 14 is decreased to a rotational speed n₁ (350 rpm in FIG. 5A). As a result, sliding is produced at the portions at which the pressers 28 and the projections 25c are brought into contact with the substrate W to move holding portions of the substrate W which are held by the pressers 28, in an opposite direction to the direction in the case where the rotational speed is increased at the acceleration α₁. At that time, the substrate W is moved relative to the substrate holding mechanisms 14, and a relative rotational speed of the substrate W to the substrate holding mechanisms 14 is gradually decreased by kinetic frictional forces produced at portions at which the pressers 28 and the projections 25c are brought into contact with the substrate W. After a predetermined period of time, the rotational speed of the substrate W and the rotational speed of the substrate holding mechanisms 14 become the same value n₁. Then, the substrate W is rotated integrally with the substrate holding mechanisms 14 while the substrate W is held at portions other than the initial holding portions.

In a case where it takes much time until the rotational speed of the substrate W reaches the same rotational speed as the substrate holding mechanisms 14 after the rotational speed of the substrate holding mechanisms 14 is changed, the rotational speed of the substrate holding mechanisms 14 may be controlled as follows. As shown in FIG. 4B or 5B, the rotational speed of the substrate holding mechanisms 14 is increased or decreased at an acceleration α₁ or β₁ to a rotational speed N₁ or n₁. The rotational speed N₁ or n₁ is maintained to be constant for a predetermined period of time (retention time T₁). Then, the rotational speed of the substrate holding mechanisms 14 is decreased or increased at an acceleration α₂ (−100 rpm/s in FIG. 4B) or β₂ (100 rpm/s in FIG. 5B) to a rotational speed N₂ or n₂, which is equal to the initial rotational speed N₀ or n₀. Thus, the rotational speed of the substrate holding mechanisms 14, which has previously been increased or decreased, is decreased or increased so as to be equal or close to the initial rotational speed. Accordingly, the rotational speed of the substrate W can quickly be made the same as the rotational speed of the substrate holding mechanisms 14.

In particular, when the rotational speed of the substrate holding mechanisms 14 is increased, the relative rotational speed of the substrate W may be decreased even though frictional forces (kinetic frictional forces) are produced at portions at which the pressers 28 and the projections 25c are brought into contact with the substrate W. In such a case, as shown in FIG. 4C, immediately after the rotational speed of the substrate holding mechanisms 14 is increased from an initial rotational speed N₀ at an acceleration α₁, the rotational speed of the substrate holding mechanisms 14 is decreased at an acceleration α₂. Then, the rotational speed of the substrate holding mechanisms 14 is maintained at a constant value N₁, which is lower than the initial rotational speed N₀. Thus, the rotational speed of the substrate W can quickly be made the same as the rotational speed of the substrate holding mechanisms 14.

Further, when holding portions of the substrate holding mechanisms 14 are shifting due to difference in rotational speed between the substrate W and the substrate holding mechanisms 14, a substrate treatment liquid may enter portions at which the projections 25c and the pressers 28 of the substrate holding mechanisms 14 are brought into contact with the substrate W. In such a case, frictional forces produced at those portions at which the projections 25c and the pressers 28 of the substrate holding mechanisms 14 are brought into contact with the substrate W may become smaller. Accordingly, in order to quickly make the rotational speed of the substrate W the same as the rotational speed of the substrate holding mechanisms 14, supply of substrate treatment liquids from the nozzles 15, 16, 11, 12, and the like is stopped at predetermined timing. For example, supply of a substrate treatment liquid from the nozzle 15 to the back surface of the substrate W is stopped while the rotational speed of the substrate holding mechanisms 14 is increased. In this case, when the relative rotational speed of the substrate W to the substrate holding mechanisms 14 is changed, the substrate treatment liquid does not enter portions at which the projections 25c and the pressers 28 are brought into contact with the substrate W. Accordingly, large frictional forces can be produced at those contacting portions. As a result, the rotational speeds of the substrate holding mechanisms 14 and the substrate W can quickly be made the same. Supply of substrate treatment liquids may not necessarily be stopped at the same time as the acceleration of the substrate holding mechanisms 14. Supply of a substrate treatment liquid from the nozzle 15 to the back surface of the substrate W may be stopped after the rotational speed of the substrate holding mechanisms 14 has been increased.

Changes of the relative rotational speed of the substrate W to the substrate holding mechanisms 14 are not limited to the aforementioned methods. For example, when an initial rotational speed of the substrate holding and rotation mechanism 20 is low, the pressers 28 are not brought into contact with the substrate W. Accordingly, the substrate W is rotated while the substrate W is not held by the pressers 28. In such a case, a substrate treatment liquid is supplied from the nozzle 15 to the back surface of the substrate W. Thus, the supplied treatment liquid can provide resistance to the substrate W so as to change the relative rotational speed of the substrate W to the substrate holding mechanisms 14. Further, a substrate treatment liquid may be supplied from the nozzle 15 to the back surface of the substrate W at an increased flow rate and flow velocity to raise the substrate W so as to form a gap between the projections 25c and the substrate W. Thus, the relative rotational speed of the substrate W to the substrate holding mechanisms 14 can be reduced.

A database regarding the amounts of movement of holding portions at which the substrate holding mechanisms 14 hold the substrate W may be prepared based on rotational operation of the substrate holding mechanisms 14, which is determined by the initial rotational speed N₀ or n₀, the rotational speed N₁ or n₁, which has been varied at the acceleration α₁ or β₁ from the initial rotational speed N₀ or n₀, the retention time T₁ to maintain the rotational speed N₁ or n₁, the rotational speed N₂ or n₂, which has been varied at the acceleration α₂ or β₂ from the rotational speed N₁ or n₁, and the retention time T₂ to maintain the rotational speed N₂ or n₂, on the timing at which supply of substrate treatment liquids are stopped, on types of films formed on the substrate W, and on process conditions of the substrate W. Rotational operation required for a desired amount of movement can be obtained from this database. The substrate holding mechanisms 14 can be rotated under the obtained conditions to process the substrate.

As shown in FIG. 1, the substrate processing apparatus 1 may include a notch/orientation flat sensor 21. The notch/orientation flat sensor 21 can detect movement of a notch or an orientation flat formed in the substrate W during processing the substrate W and measure the amount of the movement. If a desired amount of movement of substrate holding portions could not be obtained during processing the substrate W, then the aforementioned operation to change the rotational speed of the substrate holding mechanisms 14 may be repeated a predetermined number of times. Then, it may be judged whether the desired amount of movement can be obtained. Further, an alarm device (not shown) may be provided to trigger an alarm when the judgment shows that the desired amount of movement could not be obtained.

As described above, the relative rotational speed of the substrate W to the substrate holding mechanisms 14 can be changed to move holding portion at which the substrate holding mechanisms 14 hold the substrate W and to adjust the amount of movement of the holding portion at a desired value.

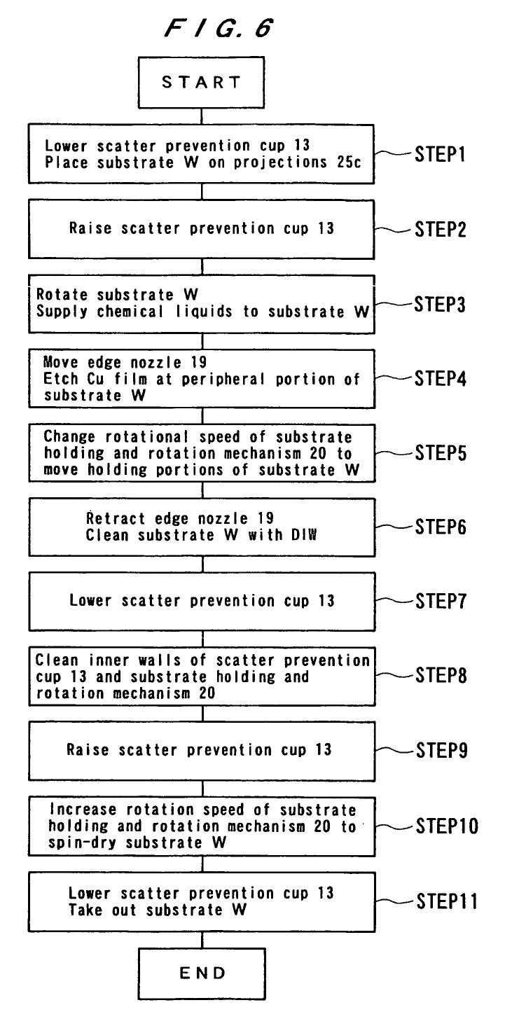

Next, there will be described an example of operation of processing a substrate with use of the substrate processing apparatus 1 described above. In this example, a substrate W is cleaned, and a bevel portion (edge portion and the vicinity thereof) of the substrate W is etched. FIG. 6 is a flowchart showing operation of this example. The example will be described with reference to FIGS. 1 and 6 through 9.

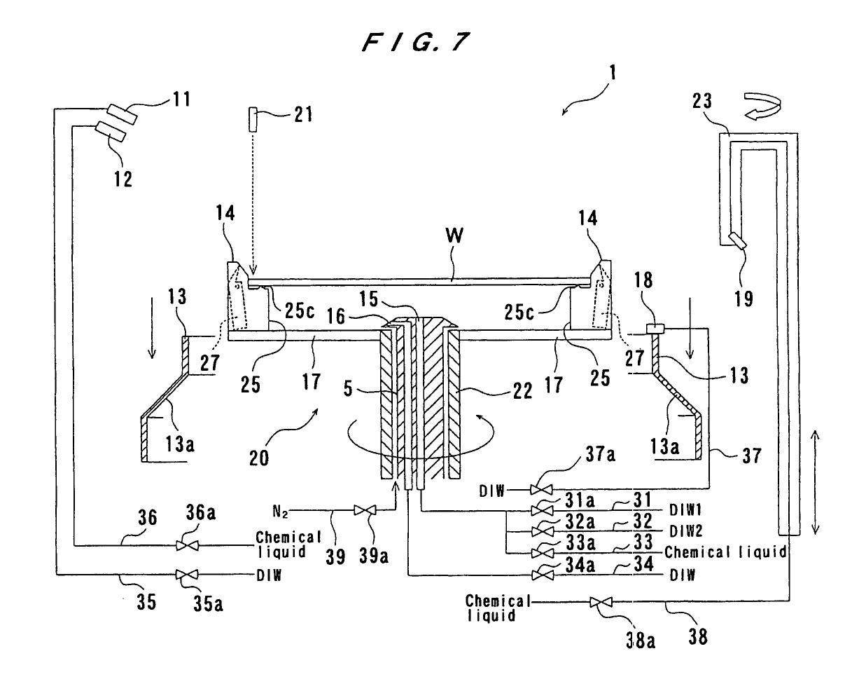

First, the scatter prevention cup 13 of the substrate processing apparatus 1 is lowered to a position shown in FIG. 7. At that time, a substrate W is transferred by a robot hand (not shown) or the like and introduced into the central portion of the substrate holding mechanisms 14. Thus, the substrate W is placed on the projections 25c (Step 1).

The scatter prevention cup 13 is raised to a position shown in FIG. 1 (Step 2).

The substrate holding and rotation mechanism 20 is rotated so as to rotate the substrate holding mechanisms 14 and the substrate W held by the substrate holding mechanisms 14 at an initial rotational speed of 350 rpm. At that time, an acceleration of the substrate holding and rotation mechanism 20 up to the initial rotational speed is set to be 400 rpm/s. At this acceleration, static frictional forces (maximum frictional forces) produced between the substrate W and the projections 25c due to the weight of the substrate W are greater than inertia forces produced on the substrate W. Accordingly, holding portions of the substrate W at which the substrate holding mechanisms 14 hold the substrate W do not slide with respect to the substrate holding mechanisms 14. Thus, the rotational speed of the substrate W does not change relative to the rotational speed of the substrate holding mechanisms 14. In a state such that the substrate W is rotated at a rotational speed of 350 rpm, sulfuric acid is supplied as a chemical liquid from the nozzle 12 to the front surface of the substrate W. Further, a mixture of sulfuric acid and oxygenated water is supplied as a chemical liquid from the nozzle 15 to the back surface of the substrate W. Thus, the substrate is processed (Step 3).

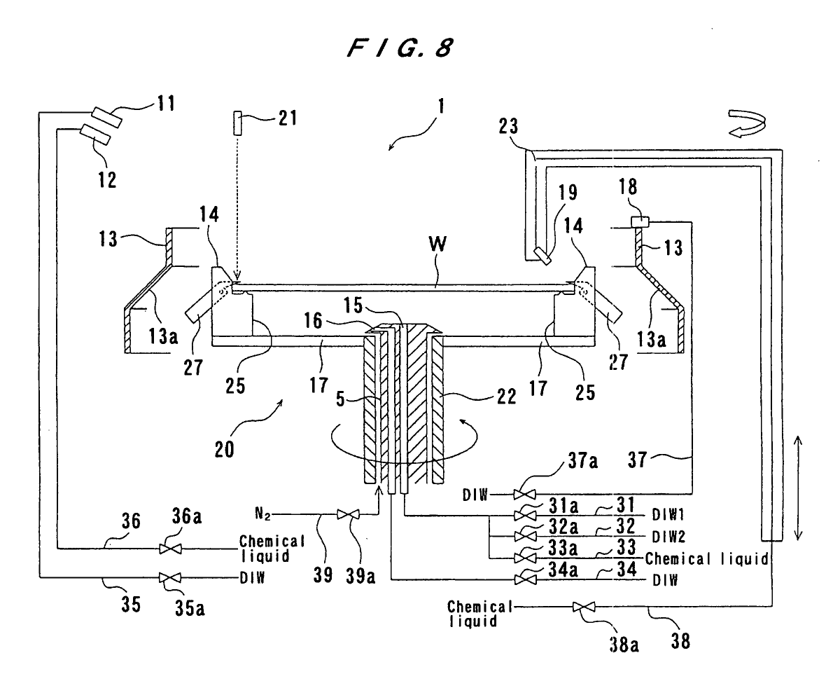

In a state such that the substrate W is rotated at a rotational speed of 350 rpm, the arm section 23 is moved upward so that the edge nozzle 19 is located higher than the scatter prevention cup 13. Then, the arm section 23 is pivoted about its axis so as to move the edge nozzle 19 above the substrate W. The edge nozzle 19 is moved downward to a position about 2 cm higher than the upper surface of the substrate W. This state is shown in FIG. 8. At that position, oxygenated water is supplied as a chemical liquid from the edge nozzle 19 to a peripheral portion of the substrate W. Specifically, oxygenated water is supplied to an area ranging 3 mm inward from an edge (peripheral edge) of the substrate W. Thus, the area ranging 3 mm inward from an edge of the substrate W is processed with a mixture of sulfuric acid supplied from the nozzle 12 and oxygenated water supplied from the edge nozzle 19. Accordingly, a Cu film formed at this area is etched (Step 4). At that state, since no treatment liquids are supplied to holding portions of the substrate W at which the substrate holding mechanisms 14 hold the substrate W, the holding portions are not etched.

After the mixture of sulfuric acid from the nozzle 12 and oxygenated water from the edge nozzle 19 is supplied for a predetermined period of time, in order to move the holding portions of the substrate held which the substrate holding mechanisms 14 hold the substrate W, the rotational speed of the substrate holding mechanisms 14 is increased to 400 rpm while the chemical liquids are supplied. At that time, an acceleration of the substrate holding mechanisms 14 is set to be 1000 rpm/s. This operation causes sliding to the holding portions of the substrate W at which the substrate holding mechanisms 14 hold the substrate W so as to move the portions of the substrate W at which the substrate holding mechanisms 14 have initially held the substrate W. Accordingly, the substrate treatment liquids can be supplied to the entire front and side surfaces of the substrate W. The rotational speed of the substrate W is increased to 400 rpm, which is the same as the rotational speed of the substrate holding mechanisms 14, after a predetermined period of time. Thus, the substrate W is rotated integrally with the substrate holding mechanisms 14 (Step 5).

The chemical liquids are further supplied to the substrate W for a predetermined period of time. Then, supply of the chemical liquid from the nozzle 12 is stopped, whereas DIW is supplied as a cleaning liquid from the nozzle 11 to the substrate W. At the same time, DIW is also supplied as a cleaning liquid from the nozzle 15, instead of a mixture of sulfuric acid and oxygenated water. The arm section 23 is moved vertically and pivoted to move the edge nozzle 19 outside of the scatter prevention cup 13. Thus, the edge nozzle 19 is retracted to a position shown in FIG. 1 (Step 6).

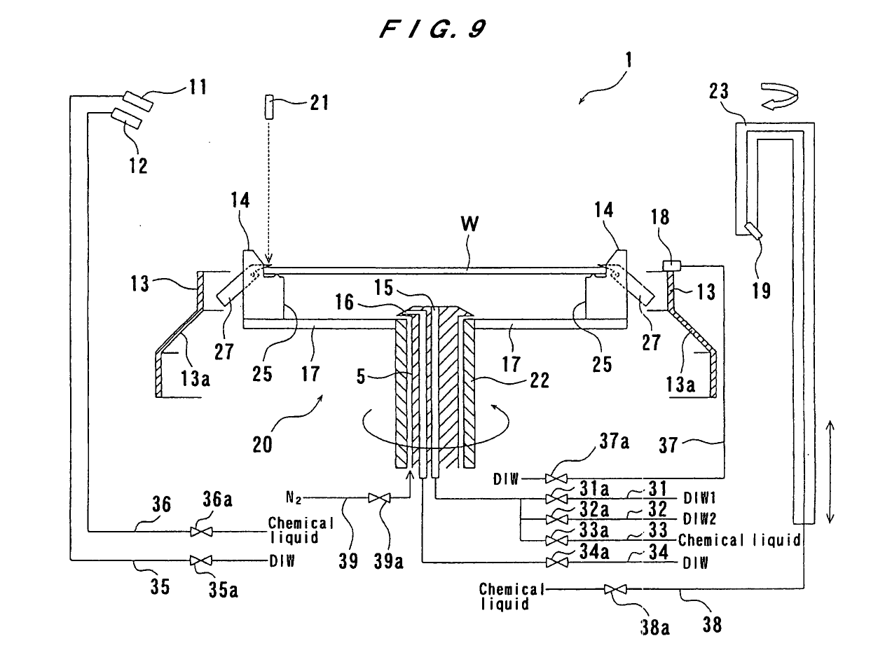

Then, the scatter prevention cup 13 is lowered to a position shown in FIG. 9 (Step 7). At that time, it is desirable that the rotational speed of the substrate holding and rotation mechanism 20 is about 100 rpm to about 300 rpm in order to prevent a substrate treatment liquid attached to the substrate W or the substrate holding mechanisms 14 from scattering on the scatter prevention cup 13 to cause splash on inner walls of the scatter prevention cup 13.

After completion of movement of the scatter prevention cup 13, DIW is supplied from the nozzle 18 to clean outer circumferential surfaces of the substrate holding mechanisms 14 and the base members 17. Further, DIW is supplied from the nozzle 16 to clean upper surfaces of the base members 17 and surfaces (inner surfaces) of the substrate holding mechanisms 14 at the rotatable shaft 22 side. Supply of DIW through the chemical liquid line 31 connected to the nozzle 15 is stopped, whereas DIW is supplied through the chemical liquid line 32. Specifically, DIW is supplied through the chemical liquid line 32 at a flow rate and a flow velocity such that DIW does not reach the back surface of the substrate W. Thus, the nozzles 15 and 16 are cleaned with DIW (Step 8).

After the above cleaning process is performed for a predetermined period of time, the scatter prevention cup 13 is raised again to the position shown in FIG. 1 (Step 9).

Then, supply of DIW from the nozzles 11, 15, 16, and 18 is stopped. The rotational speed of the substrate holding and rotation mechanism 20 is increased to 2000 rpm to spin-dry the substrate W. At that time, an acceleration of the substrate holding mechanisms 14 up to 2000 rpm is set to be 400 rpm/s. At this acceleration, holding portions of the substrate W at which the substrate holding mechanisms 14 hold the substrate W do not slide with respect to the substrate holding mechanisms 14. Thus, the rotational speed of the substrate W does not change relative to the rotational speed of the substrate holding mechanisms 14. Since inner walls of the scatter prevention cup 13 and the substrate holding and rotation mechanism 20 have been cleaned with DIW supplied in Step 8, the substrate W is spin-dried without any influence from chemical liquids (Step 10).

After the spin-drying process is performed for a predetermined period of time, rotation of the substrate holding and rotation mechanism 20 is stopped to finish the processing of the substrate W. At that time, an acceleration of the substrate holding and rotation mechanism 20 to stop the substrate holding and rotation mechanism 20 is set to be −400 rpm/s. At that acceleration, holding portions of the substrate W at which the substrate holding mechanisms 14 hold the substrate W do not slide with respect to the substrate holding mechanisms 14. Thus, the rotational speed of the substrate W does not change relative to the rotational speed of the substrate holding mechanisms 14. After rotation of the substrate W is stopped, the scatter prevention cup 13 is lowered to the position shown in FIG. 7. Then, the substrate W is taken out by the robot hand (Step 11).

According to a sequence of the above operation, it is possible to etch a Cu film formed at the area ranging 3 mm inward from the peripheral edge of the upper surface of the substrate W and at a side surface of the substrate W, and to clean the back surface of the substrate W. Further, a Cu oxide film, which is thinly formed on a surface of the Cu film, can be removed by sulfuric acid supplied to the front surface of the substrate W. If it is not necessary to remove the Cu oxide film, then DIW may be supplied from the nozzle 11 instead of supply of sulfuric acid from the nozzle 12 in Step 3, and a mixture of sulfuric acid and oxygenated water may be supplied from the edge nozzle 19 instead of supply of oxygenated water from edge nozzle 19 in Step 4.

An unnecessary film, to be removed, formed at a peripheral portion of the substrate, is not limited to a Cu film. For example, the present invention is applicable to a film containing one of Co, Co alloy such as Co—W—P or Co—W—B, Ta, Ta—N, W, W—N, Ti, Ti—N, Ni, Ru, P, B, and Mo, or to a film having a plurality of layers each containing one of these components.

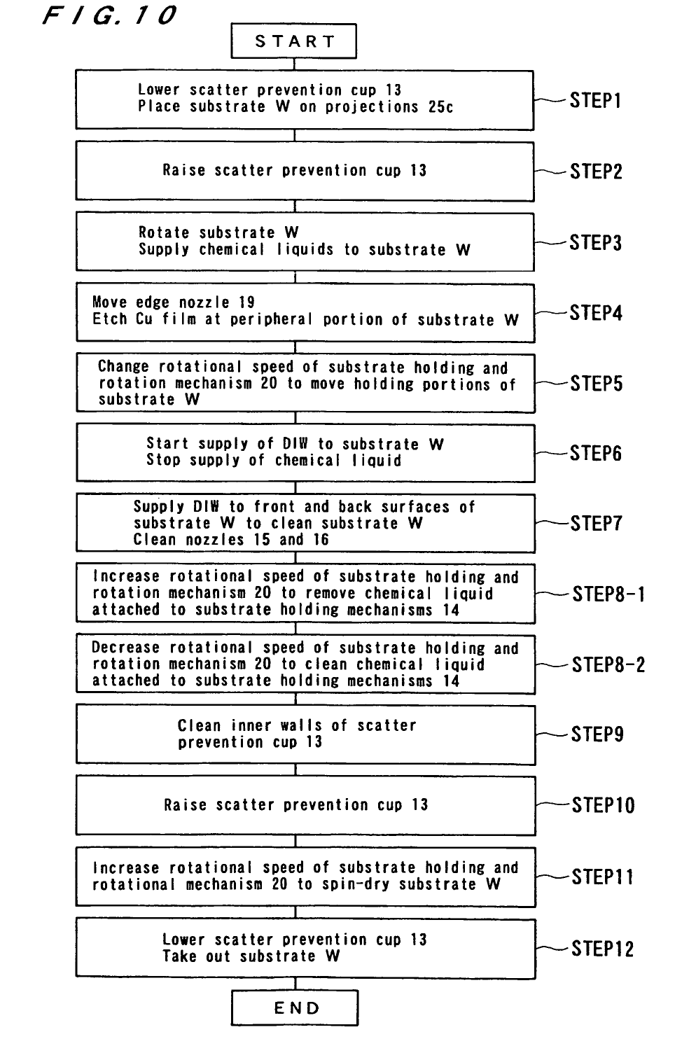

Next, there will be described another example of operation of processing a substrate with use of the substrate processing apparatus 1 described above. In this example, a substrate W is cleaned, and a bevel portion (edge portion and the vicinity thereof) of the substrate W is etched. FIG. 10 is a flowchart showing operation of this example. The example will be described with reference to FIGS. 1 and 7 through 10.

First, the scatter prevention cup 13 of the substrate processing apparatus 1 is lowered to the position shown in FIG. 7. At that time, a substrate W is transferred by a robot hand (not shown) or the like and introduced into the central portion of the substrate holding mechanisms 14. Thus, the substrate W is placed on the projections 25c of the substrate holding mechanisms 14 (Step 1).

The scatter prevention cup 13 is raised to the position shown in FIG. 1 (Step 2).

The substrate holding and rotation mechanism 20 is rotated so as to rotate the substrate holding mechanisms 14 and the substrate W held by the substrate holding mechanisms 14 at an initial rotational speed of 350 rpm. At that time, an acceleration of the substrate holding and rotation mechanism 20 up to the initial rotational speed is set to be 400 rpm/s. At this acceleration, static frictional forces (maximum frictional forces) produced between the substrate W and the projections 25c due to the weight of the substrate W are greater than inertia forces produced on the substrate W. Accordingly, holding portions of the substrate W at which the substrate holding mechanisms 14 hold the substrate W do not slide with respect to the substrate holding mechanisms 14. Thus, the rotational speed of the substrate W does not change relative to the rotational speed of the substrate holding mechanisms 14. In a state such that the substrate W is rotated at a rotational speed of 350 rpm, sulfuric acid is supplied as a chemical liquid from the nozzle 12 to the front surface of the substrate W. Further, a mixture of sulfuric acid and oxygenated water is supplied as a chemical liquid from the nozzle 15 to the back surface of the substrate W. Thus, the substrate is processed (Step 3).

In a state such that the substrate W is rotated at a rotational speed of 350 rpm, the arm section 23 is moved upward so that the edge nozzle 19 is located higher than the scatter prevention cup 13. Then, the arm section 23 is pivoted about its axis so as to move the edge nozzle 19 above the substrate W. The edge nozzle 19 is moved downward to a position about 2 cm higher than the upper surface of the substrate W. This state is shown in FIG. 8. At that position, oxygenated water is supplied as a chemical liquid from the edge nozzle 19 to a peripheral portion of the substrate W. Specifically, oxygenated water is supplied to an area ranging 3 mm inward from an edge (peripheral edge) of the substrate W. Thus, the area ranging 3 mm inward from an edge of the substrate W is processed with a mixture of sulfuric acid supplied from the nozzle 12 and oxygenated water supplied from the edge nozzle 19. Accordingly, a Cu film formed at this area is etched (Step 4). At that state, since no treatment liquids are supplied to holding portions of the substrate W at which the substrate holding mechanisms 14 hold the substrate W, the holding portions are not etched.

After the mixture of sulfuric acid from the nozzle 12 and oxygenated water from the edge nozzle 19 is supplied for a predetermined period of time, in order to move the holding portions of the substrate at which the substrate holding mechanisms 14 hold the substrate W, the rotational speed of the substrate holding mechanisms 14 is increased to 400 rpm while the chemical liquids are supplied. At that time, an acceleration of the substrate holding mechanisms 14 is set to be 1000 rpm/s. This operation causes sliding to the holding portions of the substrate W at which the substrate holding mechanisms 14 hold the substrate W so as to move the portions of the substrate W at which the substrate holding mechanisms 14 have initially held the substrate W. Accordingly, the substrate treatment liquids can be supplied to the entire front, back, and side surfaces of the substrate W. The rotational speed of the substrate W is increased to 400 rpm, which is the same as the rotational speed of the substrate holding mechanisms 14, after a predetermined period of time. Thus, the substrate W is rotated integrally with the substrate holding mechanisms 14 (Step 5).

The chemical liquids are further supplied to the substrate W for a predetermined period of time. Then, DIW is supplied as a cleaning liquid from the nozzle 11. Thereafter, supply of the chemical liquid from the nozzle 12 is stopped. In order to prevent the front surface of the substrate W from being exposed, it is desirable to stop supply of the chemical liquid from the nozzle 12 after DIW is supplied as a cleaning liquid from the nozzle 11. On the other hand, DIW is supplied as a cleaning liquid from the nozzle 15, instead of a mixture of sulfuric acid and oxygenated water. The arm section 23 is moved vertically and pivoted to move the edge nozzle 19 outside of the scatter prevention cup 13. Thus, the edge nozzle 19 is retracted to the position shown in FIG. 1 (Step 6).

DIW is supplied from the nozzles 11 and 15 to the front and back surfaces of the substrate W for a predetermined period of time to clean chemical liquids attached to the front and back surfaces of the substrate W, respectively. Further, DIW is supplied from the nozzle 16 to clean the upper surfaces of the base members 17 and surfaces (inner surfaces) of the substrate holding mechanisms 14 at the rotatable shaft 22 side. Supply of DIW through the chemical liquid line 31 connected to the nozzle 15 is stopped, whereas DIW is supplied through the chemical liquid line 32. Specifically, DIW is supplied through the chemical liquid line 32 at a flow rate and a flow velocity such that DIW does not reach the back surface of the substrate W. Thus, the nozzles 15 and 16 are cleaned with DIW (Step 7).

In a state such that DIW is supplied to the front and back surfaces of the substrate W, the rotational speed of the substrate holding and rotation mechanism 20 is increased to 2000 rpm (Step 8-1). As a result, a chemical liquid attached to the substrate holding mechanisms 14 can be blown off and removed. At that time, DIW is supplied from the nozzles 11 and 15 to the front and back surfaces of the substrate W, respectively. Accordingly, since the front and back surfaces of the substrate W are covered with DIW, even if a chemical liquid blown onto the substrate W from the substrate holding mechanisms 14, the chemical liquid is prevented from being attached to the front and back surfaces of the substrate W. Further, when a chemical liquid scatters from the substrate holding mechanisms 14 and rebounds against the scatter prevention cup 13 or the like, the chemical liquid is prevented from becoming a mist which would have an adverse influence on the front and back surfaces of the substrate W. The rotational speed of the substrate holding and rotation mechanism 20 is set to be 2000 rpm, which is equal to a rotational speed of the substrate holding and rotation mechanism 20 during a spin-drying process, which is described below. Thus, in the cleaning process, the substrate holding and rotation mechanism 20 is rotated for a desired period of time at a high rotational speed equal to the rotational speed in the spin-drying process. Accordingly, a chemical liquid attached to the substrate holding mechanisms 14 can be reliably blown off and removed.

In a state such that DIW is supplied to the front and back surfaces of the substrate W, the rotational speed of the substrate holding and rotation mechanism 20 is decreased to 50 rpm (Step 8-2). At that rotational speed, DIW supplied to the substrate W flows down on the substrate holding mechanisms 14. Accordingly, a chemical liquid attached to the substrate holding mechanisms 14 can be cleaned and removed by DIW.

Only one of the processes of Step 8-1 and Step 8-2 may be performed, or both of them may be performed. When both of the processes of Step 8-1 and Step 8-2 are performed, the order of the processes is not limited to the above example. Specifically, Step 8-2 may be performed prior to Step 8-1.

Next, the rotational speed of the substrate holding and rotation mechanism 20 is increased to 100 rpm. Then, the scatter prevention cup 13 is moved to the position shown in FIG. 9 (Step 9). At that time, it is desirable that the rotational speed of the substrate holding and rotation mechanism 20 is about 100 rpm to about 300 rpm in order to prevent a substrate treatment liquid attached to the substrate W or the substrate holding mechanisms 14 from scattering on the scatter prevention cup 13 to cause splash on inner walls of the scatter prevention cup 13. When the scatter prevention cup 13 is located at the position shown in FIG. 9, the scatter prevention cup 13 can receive DIW scattering from the substrate W or the substrate holding mechanisms 14 at upper inner walls of the scatter prevention cup 13. At that time, by adjusting the rotational speed of the substrate W and the flow rate of DIW at proper values, DIW received by the upper inner walls of the scatter prevention cup 13 flows down on the inner walls of the scatter prevention cup 13 so as to clean the inner walls of the scatter prevention cup 13.

After the cleaning process with DIW is performed for a predetermined period of time, the scatter prevention cup 13 is moved to the position shown in FIG. 1 (Step 10).

Then, supply of DIW from the nozzles 11, 15, and 16 is stopped. The rotational speed of the substrate holding and rotation mechanism 20 is increased to 2000 rpm to spin-dry the substrate W (Step 11). At that time, since the inner walls of the scatter prevention cup 13 and the substrate holding and rotation mechanism 20 have been cleaned with DIW supplied in Steps 6 to 9, the substrate W is spin-dried without any influence from chemical liquids.

After the spin-drying process is performed for a predetermined period of time, rotation of the substrate holding and rotation mechanism 20 is stopped. Thus, rotation of the substrate W is stopped to finish the processing of the substrate W. After rotation of the substrate W is stopped, the scatter prevention cup 13 is lowered to the position shown in FIG. 7. Then, the substrate W is taken out by the robot hand (Step 12).

According to a sequence of the above operation, it is possible to etch a Cu film formed at the area ranging 3 mm inward from the peripheral edge of the upper surface of the substrate W and at a side surface of the substrate W, and to clean the back surface of the substrate W. Further, a Cu oxide film, which is thinly formed on a surface of the Cu film, can be removed by sulfuric acid supplied to the front surface of the substrate W. If it is not necessary to remove the Cu oxide film, then DIW may be supplied from the nozzle 11 instead of supply of sulfuric acid from the nozzle 12 in Step 3, and a mixture of sulfuric acid and oxygenated water may be supplied from the edge nozzle 19 instead of supply of oxygenated water from edge nozzle 19 in Step 4.

An unnecessary film, to be removed, formed at a peripheral portion of the substrate, is not limited to a Cu film. For example, the present invention is applicable to a film containing one of Co, Co alloy such as Co—W—P or Co—W—B, Ta, Ta—N, W, W—N, Ti, Ti—N, Ni, Ru, P, B, and Mo, or to a film having a plurality of layers each containing one of these components.

According to the aforementioned operation, while DIW is supplied to the front and back surfaces of the substrate W in the cleaning process of Step 8-1 so as to cover the front and back surfaces of the substrate W, the substrate holding mechanisms 14 are rotated at a high rotational speed. Accordingly, a chemical liquid attached to the substrate holding mechanisms 14 can be reliably blown off and prevented from contaminating the front and back surfaces of the substrate W. Since the chemical liquid attached to the substrate holding mechanisms 14 has been removed in the spin-drying process of Step 11, the substrate W is not contaminated by the chemical liquid. Thus, a cleaning process and a drying process of a substrate can be performed in a single apparatus. Accordingly, it is possible to prevent an increased footprint of the substrate processing apparatus and improve a throughput of the substrate processing apparatus. Pure water, deaerated water, gas dissolved water, or the like may be used as the cleaning liquids described above.

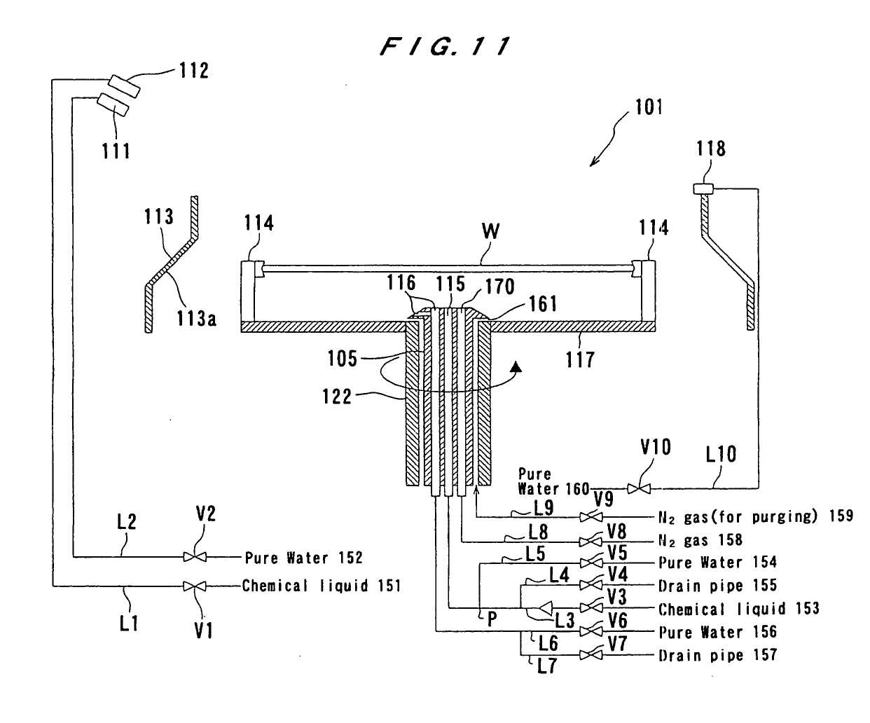

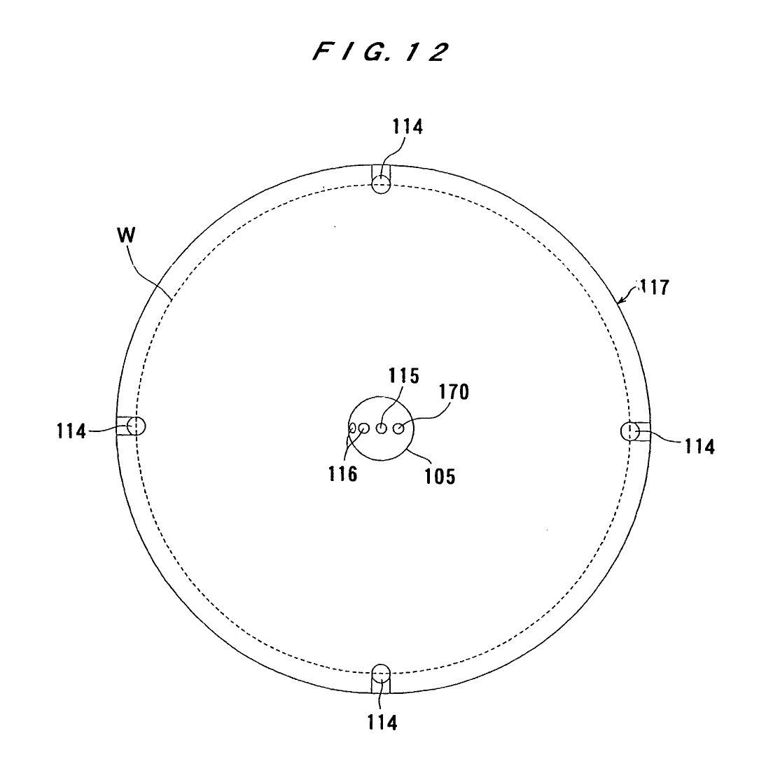

FIG. 11 is a side view showing a substrate processing apparatus 101 according to a second embodiment of the present invention, and FIG. 12 is a plan view showing substrate holding mechanisms (substrate holding chucks) 114 and a base member (chuck holding base) 117 in the substrate processing apparatus 101 shown in FIG. 11. The substrate processing apparatus 101 has a circular base member 117, at least three substrate holding mechanisms 114 (four substrate holding mechanisms in FIG. 12) provided near a peripheral portion of the base member 117 (at positions a predetermined distance inward from a periphery of the base member 117) for holding a substrate W such as a semiconductor wafer, and a rotatable shaft 122 attached to a central portion of the base member 117. The base member 117 is rotated about the rotatable shaft 122 by a driving device (not shown) while the substrate W is held by the substrate holding mechanisms 114. The base member 117 is slightly larger than the substrate W and thus covers the entire lower surface of the substrate W. Accordingly, a liquid scattering from the substrate W is prevented from being spattered on the base member 117 and attached to the lower surface of the substrate W when the substrate W is dried by high-speed rotation.

The substrate processing apparatus 101 includes a chemical liquid supply nozzle 112 connected to a chemical liquid line L1, which has a valve V1 provided thereon, and a cleaning liquid supply nozzle 111 connected to a pure water line L2, which has a valve V2 provided thereon. When the valve V1 is opened to supply a chemical liquid 151 to the chemical liquid supply nozzle 112, the chemical liquid 151 is supplied from the chemical liquid supply nozzle 112 to an upper surface of the substrate W. When the valve V2 is opened to supply pure water (DIW) 152 to the cleaning liquid supply nozzle 111, the pure water 152 is supplied to the upper surface of the substrate W.

The substrate processing apparatus 101 also includes a nozzle structure 105 extending through the rotatable shaft 122. The nozzle structure 105 is disposed at a central portion of the base member 117 located below the substrate W. The nozzle structure 105 includes three nozzles 115, 116, and 170. The nozzle 115 is connected to a chemical liquid line L3, which has a valve V3 provided thereon, a pure water line L5, which has a valve V5 provided thereon, and a discharge water line L4, which has a valve V4 provided thereon. Thus, a chemical liquid 153 and pure water 154 can be supplied through the chemical liquid line L3 and the pure water line L5 to the nozzle 115, respectively. The discharge water line L4 is connected to a drain pipe 154. The nozzle 116 is connected to a pure water line L6, which has a valve V6 provided thereon, and a discharge water line L7, which has a valve V7 provided thereon. Pure water 156 is supplied through the pure water line L6 to the nozzle 116. The discharge water line L7 is connected to a drain pipe 157. The nozzle 170 is connected to a gas line L8, which has a valve V8 provided thereon. N₂ gas 158 is supplied through the gas line L8 to the nozzle 170. A gap 161 between the rotatable shaft 122 and the nozzle structure 105 is connected to a purge gas supply line L9, which has a valve V9 provided thereon. N₂ gas 159 is supplied as a purge gas through the purge gas supply line L9 to the gap 161.

The substrate processing apparatus 101 has a scatter prevention cup 113 disposed so as to surround the substrate holding mechanisms 114 and the base member 117. The scatter prevention cup 113 has a nozzle 118 provided at an upper end of the scatter prevention cup 113. The nozzle 118 is connected to a pure water line L10, which has a valve V10 provided thereon. Pure water 160 is supplied through the pure water line L10 to the nozzle 118.

The chemical liquid 153 and the pure water 154 can be selectively supplied to the nozzle 115 by the valves V3 and V5. Thus, the chemical liquid 153 and the pure water 154 are selectively supplied from the nozzle 115 to the lower surface of the substrate W. Liquid (mainly pure water 154) is supplied from the nozzle 115 at a flow rate such that the liquid does not reach the substrate W. A flow rate such that the liquid does not reach the substrate W is defined as the amount of flow per unit time such that the liquid is not blown from the nozzle 115 directly to the substrate W, or as the amount of flow per unit time such that the liquid spills from the nozzle 115. As a result, the liquid can flow on an upper surface of the nozzle structure 105 to thereby clean the nozzle structure 105 (the nozzle 115 and the vicinity thereof). The nozzle 115 is connected through the valve V4 to a drain pipe 155. When the valves V3 and V5 are closed and only the valve V4 is opened, a liquid remaining within the nozzle 115 and the lines connected to the nozzle 115 can be discharged to the drain pipe 155.

In the present embodiment, the interiors of the lines (the chemical liquid line L3, the pure water line L5, and the discharge water line L4) connected to the nozzle 115 and the nozzle structure 105 can be cleaned. First, the valve V3 is opened to supply a chemical liquid 153 through the chemical liquid line L3 to the nozzle 115, and the chemical liquid 153 is supplied from the nozzle 115 to the substrate W. Then, the valve V3 is closed and the valve V4 is opened to withdraw a liquid in the lines connected to the nozzle 115. Thus, the chemical liquid 153 in the lines connected to the nozzle 115 can immediately be discharged to the drain pipe 155. Next, the valve V4 remains opened, and the valve V5 is opened. Accordingly, pure water 154 can flow from a branch point P of the pure water line L5 and the chemical liquid line L3 to the discharge water line L4, to thereby clean the interiors of the lines. Further, the valve V5 remains opened, and the valve V4 is closed. Accordingly, pure water 154 can flow from the branch point P of the pure water line L5 and the chemical liquid line L3 to the nozzle 115, to thereby clean the interiors of the lines.

Since pure water 154 is supplied from the nozzle 115 at a flow rate such that the pure water 154 does not reach the lower surface of the substrate W, the nozzle structure 105 including the nozzles 115, 116, and 170 can be cleaned. It is important to previously clean the branch point P of the pure water line L5 and the chemical liquid line L3. If the branch point P has not been cleaned, pure water containing a slight amount of chemical liquid 153 is continuously supplied from the nozzle 115.

Before the substrate W is spin-dried, only the valve V4, which is connected to the nozzle 115, is opened to discharge a liquid in the nozzle 115 and the interiors of the lines connected to the nozzle 115 through the drain pipe 155. When the substrate W is rotated at a high rotational speed during the spin-drying process or the like, a negative pressure can be developed between the substrate W and the base member 117. Thus, it is possible to prevent a liquid in the nozzle 115 and the interiors of the lines connected to the nozzle 115 from being ejected from the nozzle 115. Accordingly, the substrate can effectively be dried. If a chemical liquid remains in the nozzle structure 105 including the nozzles 115, 116, and 170, a negative pressure is developed between the substrate W and the base member 117 during the spin-drying process. Accordingly, the chemical liquid may scatter and be problematically attached to the substrate W.

The nozzle 116 can supply a liquid like a spray. When the valve V7 is closed and the valve V6 is opened, pure water 156 is supplied through the pure water line L6 to the nozzle 116. Thus, the pure water 156 is supplied from the nozzle 116 to the lower surface of the substrate W, the upper surface of the base member 117, and inner surfaces of the substrate holding mechanisms 114 to clean these surfaces. Cleaning of the nozzle structure 105 and cleaning of the base member 117 and the inner surfaces of the substrate holding mechanisms 114 by the nozzle 116 results in cleaning of all members that cover the lower surface of the substrate W. Further, before the spin-drying process, only the valve V7 is opened to discharge a liquid in the lines connected to the nozzle 116 through the discharge water line L7 to the drain pipe 157. Thus, as described in connection with the nozzle 115, even if a negative pressure is developed between the substrate W and the base member 117 during the spin-drying process or the like, it is possible to prevent a liquid in the nozzle 115 and the interiors of the lines connected to the nozzle 116 from being ejected from the nozzle 115. Accordingly, the substrate can effectively be dried.

The nozzle 170 can supply a N₂ gas 158 through the gas line L8 and the valve V8. Accordingly, the space between the substrate W and the base member 117 can be filled with the N₂ gas 158 so as to maintain the space at a high pressure, preferably at a pressure higher than the exterior of the space (even during the spin-drying process). Thus, it is possible to prevent a chemical liquid or a mist thereof from being introduced into the space between the lower surface of the substrate W and the base member 117. Further, the N₂ gas can blow a liquid present on a central portion of the lower surface of the substrate W. Accordingly, the N₂ gas can help to dry the central portion of the lower surface of the substrate W, from which a liquid is unlikely to be blown off by spin-drying. The N₂ gas is supplied mainly during the drying process of the substrate W to prevent introduction of a chemical liquid or a mist thereof and help to dry the substrate. When members including the nozzle 170, which supplies a N₂ gas, are cleaned with a cleaning liquid, the cleaning liquid may enter the nozzle 170. Accordingly, when the nozzle structure IOs including the nozzles 115, 116, and 170 is cleaned, or when the back surface of the substrate W is processed with a chemical liquid supplied from the nozzle 115, or when all members that cover the lower surface of the substrate W are cleaned with pure water supplied from the nozzle 116, a N₂ gas is supplied to a flow rate such that a liquid does not enter the nozzle 170. Thus, it is possible to prevent a liquid that has entered the nozzles 170 from being ejected during the drying process to exert an adverse influence on the drying process.

Generally, pure water (DIW) or gas dissolved water can be used as a cleaning liquid for the substrate W. However, chemical liquids may be used according to purposes of cleaning. The gas to be supplied to the lower surface of the substrate W may comprise a N₂ gas or dried air and is not limited to these examples. For example, various kinds of inert gases may be used.

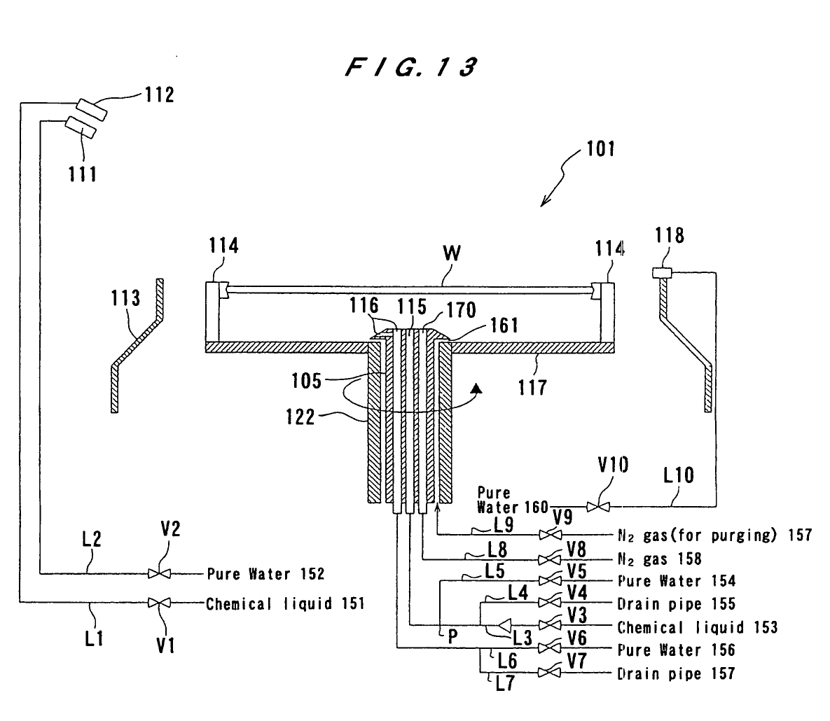

In FIG. 11, the scatter prevention cup 113 can receive a chemical liquid for processing the substrate W to prevent scattering of the chemical liquid. At the position shown in FIG. 11, the scatter prevention cup 113 receives a substrate treatment liquid such as a chemical liquid or a cleaning liquid mainly by an inclined portion 113a of the scatter prevention cup 113. FIG. 13 shows that the scatter prevention cup 113 is moved to a position where inner walls of the scatter prevention cup 113 are cleaned. At the position shown in FIG. 13, the scatter prevention cup 113 receives a cleaning liquid by upper portions of the scatter prevention cup 113. By setting the rotational speed of the substrate W and the flow rate of the cleaning liquid at proper values, the cleaning liquid received by the upper portions of the inner walls flows downward on the inner walls of the scatter prevention cup 113 so as to clean the inner walls of the scatter prevention cup 113. Pure water 160 is supplied through the valve V10 and the pure water line L10 to the nozzle 118. The nozzle 118 jets the pure water 160 like a spray. The nozzle 118 can supply the pure water 160 to outer surfaces of the substrate holding mechanisms 114 and a side surface of the base member 117 to clean these surfaces.

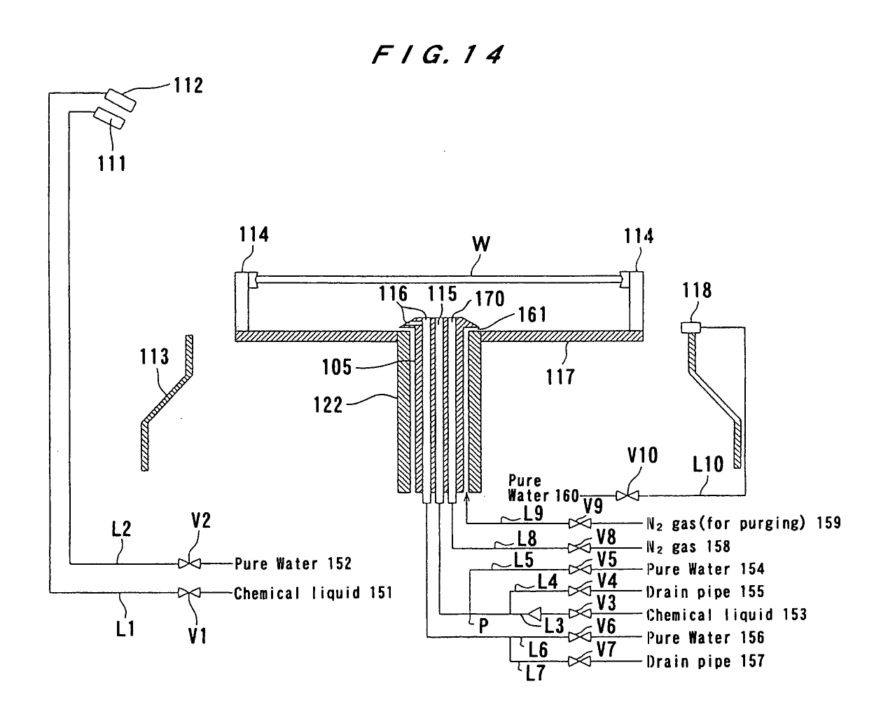

FIG. 14 shows the scatter prevention cup 113 when the substrate W is transferred into and from the substrate processing apparatus 101. In FIG. 14, the substrate W is transferred into and from the substrate processing apparatus 101 near the scatter prevention cup 113 by a robot or the like. During processing substrate W, the valve V9 is continuously opened to supply a N₂ gas as a purge gas to the gap 161 formed between the rotatable shaft 122 and the nozzle structure 105. Thus, it is possible to prevent a liquid or a mist from being enter the rotatable shaft 122.

There will be described below an example in which a semiconductor wafer is used as a substrate W to be processed in the substrate processing apparatus 101 having the above arrangement. The following processes of Steps 1 to 9 are performed on a semiconductor wafer having a bare Si surface facing upward.

The scatter prevention cup 113 is moved to a position shown in FIG. 14, i.e., to a position such that the substrate holding mechanisms 114 are located a predetermined distance above an upper end of the scatter prevention cup 113. At that state, the substrate processing apparatus 101 receives the substrate W transferred by a robot hand or the like and holds a peripheral portion of the substrate W by the substrate holding mechanisms 114 (Step 1).

Then, the scatter prevention cup 113 is raised to a position shown in FIG. 11, i.e., to a position such that the upper end of the scatter prevention cup 113 is located a predetermined distance above upper ends of the substrate holding mechanisms 114 (Step 2).

The base member 117, the substrate holding mechanisms 114, and the substrate W are rotated at about 500 rpm. The valve V1 is opened to supply hydrofluoric acid as a chemical liquid 151 through the chemical liquid line L1 to the chemical liquid supply nozzle 112. Thus, the chemical liquid 151 is supplied from the chemical liquid supply nozzle 112 to the upper surface of the substrate W. The valve V3 is opened to supply the hydrofluoric acid as a chemical liquid 153 to the nozzle 115. Thus, the chemical liquid 153 is supplied from the nozzle 115 to the lower surface of the substrate W (Step 3).

Hydrofluoric acid is supplied as the chemical liquid 151 from the chemical liquid supply nozzle 112 for a predetermined period of time. Then, the valve V1 is closed to stop supply of the chemical liquid 151. In order to prevent exposure of the surface of the substrate W, it is desirable to open the valve V2 before the valve V1 is closed. In this case, pure water can be supplied from the chemical liquid supply nozzle 111 before supply of the chemical liquid from the chemical liquid supply nozzle 112 is stopped. Thus, the pure water 152 and the chemical liquid 151 can concurrently be supplied onto the upper surface of the substrate W. The valve V6 is opened to supply pure water 156 from the nozzle 116. The valve V3 is closed to stop supply of the chemical liquid 153 from the nozzle 115. The valve V4 is opened to discharge a liquid in the lines connected to the nozzle 115 to the drain pipe 155 (Step 4).

Pure water 152 and pure water 156 are supplied from the cleaning liquid supply nozzle 111 and the nozzle 116 to the upper and lower surfaces, respectively, for a predetermined period of time to clean a chemical liquid remaining on the upper and lower surfaces of the substrate W. At that time, pure water 156 is supplied from the nozzle 116 to clean the upper surface of the base member 117 and the inner surfaces of the substrate holding mechanisms 114. When the chemical liquid remaining on the upper and lower surfaces of the substrate W is cleaned, the valve V5 is opened after the valve V4 is closed. Thus, pure water 154 is supplied from the nozzle 115. The pure water 154 is supplied from the nozzle 115 at a flow rate such that the pure water 154 does not reach the lower surface of the substrate W. Accordingly, the nozzle structure 105 including the nozzles 115, 116, and 170 are cleaned. The valve V8 is opened to supply a N₂ gas to the nozzle 170. Thus, the gas is blown until the drying process to prevent pure water from entering the nozzle 170 (Step 5).

The rotational speed of the base member 117, the substrate holding mechanisms 114, and the substrate W is decreased to 100 rpm. Then, the scatter prevention cup 113 is moved to a position shown in FIG. 13. This movement allows pure water scattering from the substrate W to be supplied to the inner walls of the scatter prevention cup 113. Thus, the inner walls of the scatter prevention cup 113 can be cleaned with pure water. The valve V10 is opened to clean the outer surfaces of the substrate holding mechanisms 114 and the side surface of the base member 117 (Step 6). In order to prevent splash on the inner walls of the scatter prevention cup 113, the rotational speed of the base member 117, the substrate holding mechanisms 114, and the substrate W is preferably in a range of about 100 to about 300 rpm.

After cleaning is performed for a predetermined period of time, the scatter prevention cup 113 is moved to the position shown in FIG. 11 (Step 7).

The valve V2 is closed to stop supply of pure water 152 to the cleaning liquid supply nozzle 111. The valves V5 and V6 are closed to stop supply of pure water to the nozzles 115 and 116. Then, the valves V4 and V7 are opened for a second to discharge a liquid in the nozzles 115 and 116 and the lines connected to the nozzles 115 and 116 to the drain pipes 155 and 157 (Step 8). Thus, it is possible to minimize the amount of liquid in the vicinity of the nozzle structure 105 including the nozzles 115, 116, and 170.

After the valves V4 and V7 are closed, the rotational speed of the base member 117, the substrate holding mechanisms 114, and the substrate W is increased. The base member 117, the substrate holding mechanisms 114, and the substrate W are rotated at 2000 rpm for a predetermined period of time (Step 9). This operation allows a liquid attached to the substrate W to be blown by centrifugal forces, thereby effectively drying the substrate W.

Particularly, the lower surface of the substrate can effectively processed with protection of the lower surface of the substrate W and prevention of entry of the mist in Step 9. Since the lower surface of the substrate W is protected by the base member 117, it is possible to prevent a liquid from rebounding from the surroundings. Since the N₂ gas is supplied to the space between the substrate W and the base member 117, it is possible to prevent a mist from being introduced from the surroundings. The base member 117, which faces the lower surface of the substrate, and the nozzle structure 105 including the nozzles 115, 116, and 170 are cleaned. Liquid in the nozzles 115 and 116 and the lines connected thereto is discharged. Accordingly, the liquid is not blown by acceleration or deceleration of the substrate W. The gas is supplied so that the treatment liquid is not collected in the nozzle 170 in Steps 5 to 8. Accordingly, the gas is effectively supplied during the drying process.

Since the inner and outer surfaces of the substrate holding mechanisms 114 and the inner walls of the scatter prevention cup 113 are cleaned even though a chemical liquid is spattered on the inner walls of the scatter prevention cup 113, a mist of a chemical liquid is not generated on the inner walls of the scatter prevention cup 113. Accordingly, a bare Si substrate W can be processed without any watermark produced on the lower surface of the substrate W, any chemical liquid remained on the lower surface of the substrate W, or any influences from an atmosphere.

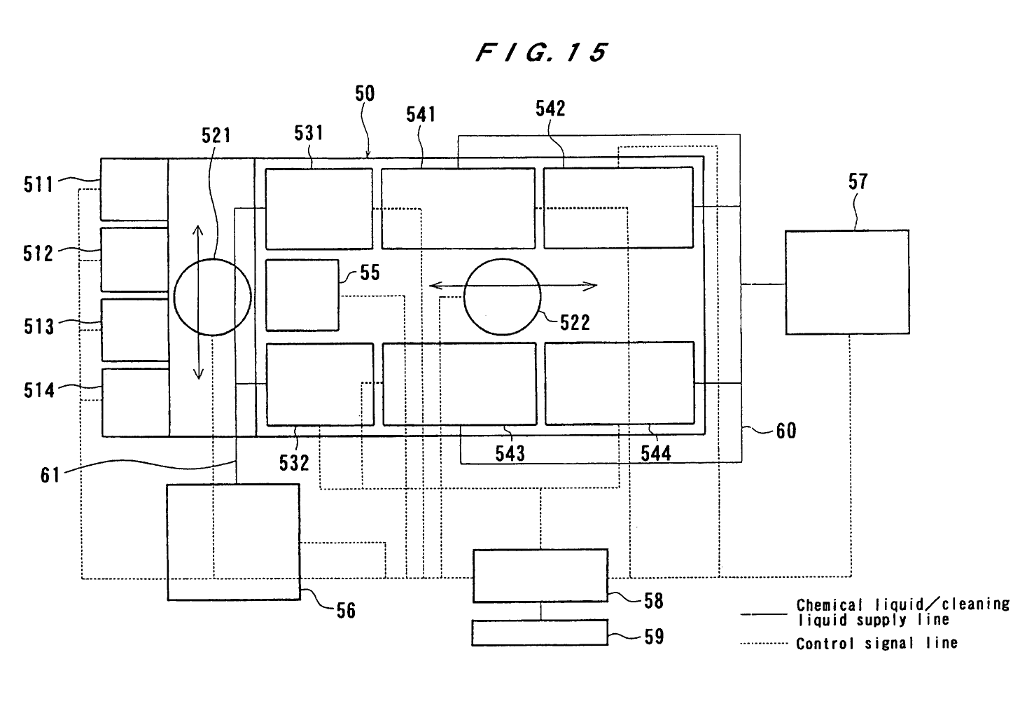

FIG. 15 is a plan view showing a Cu plating apparatus 50 incorporating a substrate processing apparatus according to the present invention. As shown in FIG. 15, the Cu plating apparatus 50 has substrate cassettes 511, 512, 513, and 514, substrate transfer robots 521 and 522, cleaning tanks 531 and 532, plating tanks 541, 542, 543, and 544, and a substrate stage 55. Each of the cleaning tanks 531 and 532 includes a substrate processing apparatus according to the present invention. The cleaning tanks 531 and 532 are connected to a cleaning liquid supply device 56. The plating tanks 541, 542, 543, and 544 are connected to a plating liquid supply device 57. The Cu plating apparatus 50 also includes a display 59 and a controller 58, which sends control signals to the respective components in the Cu plating apparatus 50.

In the Cu plating apparatus 50, the substrate transfer robot 521 takes out one of unprocessed substrates W from one of the substrate cassettes 511 to 514 based on control signals sent from the controller 58 and places it on the substrate stage 55. The substrate W placed on the substrate stage 55 is sequentially transferred to the plating tanks 541 to 544 by the substrate transfer robot 522. In the plating tanks 541 to 544, Cu plating is conducted on a surface of the substrate W. Then, the substrate W is transferred to the cleaning tanks 531 and 532 by the substrate transfer robot 522. In the cleaning tanks 531 and 532, cleaning and etching are conducted on the surface of the substrate W. Plating liquids to be used in the plating tanks 541 to 544 are supplied from the plating liquid supply device 57. Cleaning liquids to be used in the cleaning tanks 531 and 532 are supplied from the cleaning liquid supply device 56.

The Cu plating apparatus 50 controls the cleaning liquid supply device 56, the plating liquid supply device 57, and additional devices (not shown) including a measurement device by control signals sent from the controller 58. The controller 58 sends control signals to the respective devices such as the cleaning liquid supply device 56 and the plating liquid supply device 57 so as to perform operation in accordance with an inputted recipe. According to the control signals, valves (not shown) provided in a plating solution supply line 60 and a cleaning liquid supply line 61 are opened and closed, respectively, and motors (not shown) are driven. Further, a flowmeter or the like may be provided. In this case, signals from the flowmeter may be inputted into the controller 58 so that feed back control can be performed so as to conform a measured value to a preset value. If the measured value is out of a predetermined tolerance, or if the flowmeter outputs a warning signal, then the apparatus may be stopped. The cleaning liquid supply device 56, the plating liquid supply device 57, the controller 58, the display 59, and the like may be provided within a frame of the Cu plating apparatus 50.

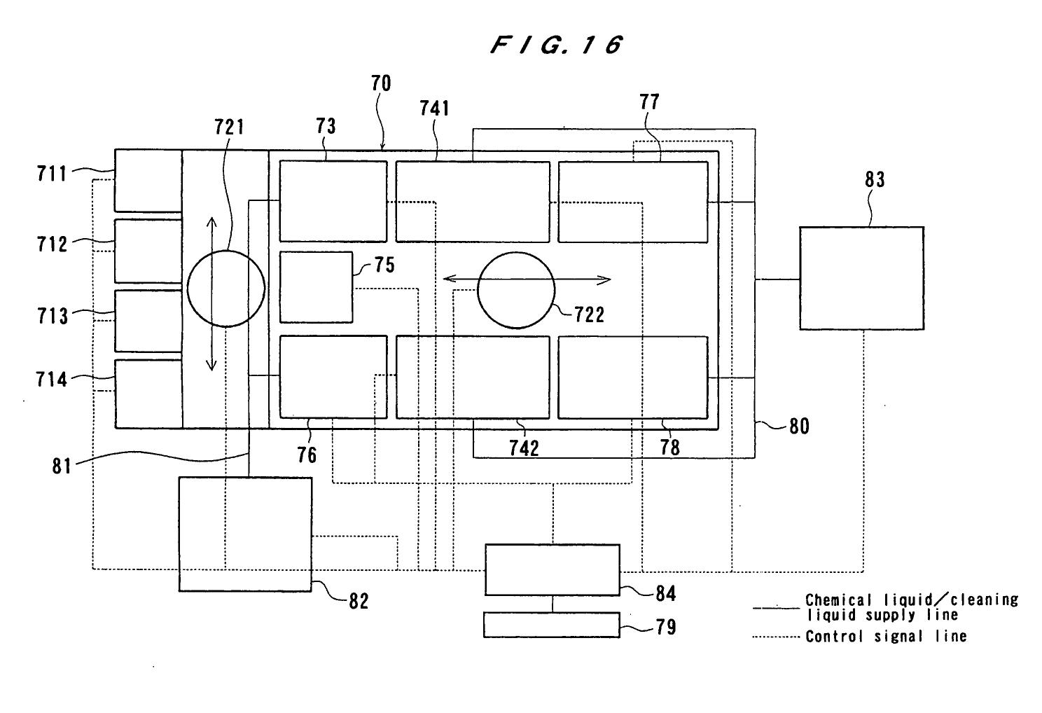

FIG. 16 is a plan view showing an electroless plating apparatus 70 incorporating a substrate processing apparatus according to the present invention. As shown in FIG. 16, the electroless plating apparatus 70 has substrate cassettes 711, 712, 713, and 714, substrate transfer robots 721 and 722, a cleaning tank 73, a roll-type cleaning device 76, electroless plating tanks 741 and 742, a pretreatment tank 77, a seed application tank 78, and a substrate stage 75. The cleaning tank 73 includes a substrate processing apparatus according to the present invention. The cleaning tank 73 and the roll-type cleaning device 76 are connected to a cleaning liquid supply device 82. The electroless plating tanks 741 and 742, the pretreatment tank 77, and the seed application tank 78 are connected to a chemical liquid supply device 83. The electroless plating apparatus 70 also includes a display 79 and a controller 84, which sends control signals to the respective components in the electroless plating apparatus 70.

In the electroless plating apparatus 70, the substrate transfer robot 721 takes out one of unprocessed substrates W from one of the substrate cassettes 711 to 714 based on control signals sent from the controller 84 and places it on the substrate stage 75. The substrate W placed on the substrate stage 75 is transferred to the pretreatment tank 77 by the substrate transfer robot 722. In the pretreatment tank 77, pretreatment is performed on the substrate W. The substrate W is transferred to the seed application tank 78, where a seed layer is formed on a surface of the substrate. Then, the substrate W is transferred to the electroless plating tanks 741 and 742, where a plating film is formed on the surface of the substrate. The substrate W having the plating film is transferred to the cleaning tank 73, where cleaning and etching are conducted on the surface of the substrate W.

There will be described an example of operation of the substrate processing apparatus in the cleaning tank 73 with reference to FIG. 1. Sulfuric acid is supplied as a chemical liquid to the surface of the substrate W from the nozzle 12. A mixture of sulfuric acid and oxygenated water is supplied from the nozzle 15 to the back surface of the substrate W. Further, oxygenated water is supplied from the edge nozzle 19 to an edge portion of the substrate W. Thus, the edge portion of the substrate W is etched by a mixture of the oxygenated water and sulfuric acid supplied from the nozzle 12. Alternatively, DIW may be supplied from the nozzle 11 to the surface of the substrate W, a mixture of sulfuric acid and oxygenated water may be supplied from the nozzle 15 to the back surface of the substrate W, and a mixture of sulfuric acid and oxygenated water may be supplied from the edge nozzle 19 to an edge portion of the substrate W.

After the above processes are completed, DIW is supplied from the nozzles 11 and 15 to the front and back surfaces of the substrate W to clean the substrate W, respectively. Then, the substrate W is transferred to the roll-type cleaning device 76. Plating liquids to be used in the electroless plating tanks 741 and 742, a pretreatment liquid to be used in the pretreatment tank 77, and a seed application liquid to be used in the seed application tank 78 are supplied from the chemical liquid supply device 83. Cleaning liquids to be used in the cleaning tank 73 and the roll-type cleaning device 76 are supplied from the cleaning liquid supply device 82.

The electroless plating apparatus 70 controls the cleaning liquid supply device 82, the chemical liquid supply device 83, and additional devices (not shown) including a measurement device by control signals sent from the controller 84. The controller 84 sends control signals to the respective devices such as the cleaning liquid supply device 82 and the chemical liquid supply device 83 so as to perform operation in accordance with an inputted recipe. According to the control signals, valves (not shown) provided in a chemical liquid supply line 80 and a cleaning liquid supply line 81 are opened and closed, respectively, and motors (not shown) are driven. Further, a flowmeter or the like may be provided. In this case, signals from the flowmeter may be inputted into the controller 84 so that feed back control can be performed so as to conform a measured value to a preset value. If the measured value is out of a predetermined tolerance, or if the flowmeter outputs a warning signal, then the apparatus may be stopped. The cleaning liquid supply device 82, the chemical liquid supply device 83, the controller 84, the display 79, and the like may be provided within a frame of the electroless plating apparatus 70.

Substrate treatment to be performed in the substrate processing apparatus is not limited to the treatment described in the above embodiments. For example, by changing positions at which the nozzles are provided, types of cleaning liquids or chemical liquids supplied from the nozzles, and timing to supply cleaning liquids or chemical liquids, the substrate processing apparatus can be configured to perform appropriate treatment suitable for the type of the substrate. Further, any shapes, structures, and materials not disclosed directly in the specification or drawings are included in the scope of the present invention as long as they have advantageous effects of the present invention as described above.

Although certain preferred embodiments of the present invention have been shown and described in detail, it should be understood that various changes and modifications may be made therein without departing from the scope of the appended claims.

### INDUSTRIAL APPLICABILITY

The present invention is suitable for use in a substrate processing apparatus for processing a rotating substrate such as a semiconductor wafer while supplying a treatment liquid to the substrate

1. A substrate processing apparatus comprising:
a substrate holding mechanism for holding a substrate under a holding force which is produced due to a centrifugal force caused by rotation of said substrate holding mechanism;
a substrate rotation mechanism for rotating said substrate holding mechanism to rotate the substrate held by said substrate holding mechanism;
a driving device for changing a rotational speed of said substrate holding mechanism so as to change the holding force under which the substrate is held by said substrate holding mechanism; and
a treatment liquid supply mechanism for supplying a treatment liquid to a desired portion of the substrate held by said substrate holding mechanism.

2. (canceled)

3. A substrate processing apparatus comprising:
a substrate holding mechanism for holding a peripheral portion of a substrate;
a base member having said substrate holding mechanism attached thereto, said base member facing at least one surface of the substrate;
a rotatable shaft attached to a central portion of said base member;
a first liquid supply nozzle for selectively supplying a chemical liquid or a first cleaning liquid to the substrate;
a switching device for switching the chemical liquid and the first cleaning liquid to be supplied to said first nozzle;
a second liquid supply nozzle for supplying a second cleaning liquid to an inner surface of said substrate holding mechanism and an upper surface of said base member;
a gas supply nozzle for supplying a gas to a space between the substrate and said base member;
a nozzle structure including said first liquid supply nozzle, said second liquid supply nozzle, and said gas supply nozzle, said nozzle structure being disposed within said rotatable shaft; and
a purge gas supply line for supplying a purge gas to a gap between said rotatable shaft and said nozzle structure.

4. The substrate processing apparatus as recited in claim 3, wherein said first liquid supply nozzle is configured to clean said first liquid supply nozzle, an outer surface of said nozzle structure, and vicinity thereof with the first cleaning liquid.

5. The substrate processing apparatus as recited in claim 3, further comprising:
a first line connected to said first liquid supply nozzle;
a second line connected to said second liquid supply nozzle; and
a liquid discharge mechanism for discharging a liquid remaining in said first line and said second line.

6. (canceled)

7. The substrate processing apparatus as recited in claim 3, further comprising a third liquid supply nozzle for supplying a third cleaning liquid to an outer surface of said substrate holding mechanism.

8. The substrate processing apparatus as recited in claim 1, further comprising a scatter prevention cup disposed outside of said substrate holding mechanism so as to cover said substrate holding mechanism, said scatter prevention cup being movable in a vertical direction.

9. A substrate processing method comprising:
holding a substrate by a substrate holding mechanism under a holding force which is produced due to a centrifugal force caused by rotation of the substrate holding mechanism;
rotating the substrate holding mechanism by a substrate rotation mechanism to rotate the substrate;
changing a rotational speed of the substrate holding mechanism so as to change the holding force under which the substrate is held by the substrate holding mechanism; and
supplying a treatment liquid to a desired portion of the rotating substrate to process the substrate while said changing a rotational speed of the substrate holding mechanism.

10. The substrate processing method as recited in claim 9, wherein said changing a rotational speed of the substrate holding mechanism comprises:
increasing or decreasing the rotational speed of the substrate holding mechanism to change the rotational speed of the substrate holding mechanism and the rotational speed of the substrate relative to each other.

11. The substrate processing method as recited in claim 10, wherein said changing a rotational speed of the substrate holding mechanism comprises:
stopping said supplying the substrate treatment liquid simultaneously with or after said increasing or decreasing the rotational speed of the substrate holding mechanism.

12. The substrate processing method as recited in claim 9, wherein said changing a rotational speed of the substrate holding mechanism comprises:
changing the rotational speed of the substrate holding mechanism from a first rotational speed to a second rotational speed; and then
returning the rotational speed of the substrate holding mechanism from the second rotational speed to the first rotational speed.

13. A substrate processing method comprising:
holding a substrate by a substrate holding mechanism;
rotating the substrate holding mechanism by a substrate rotation mechanism to rotate the substrate;
supplying a treatment liquid to the rotating substrate to process the substrate;
rotating the substrate at a first high rotational speed after said supplying the treatment liquid;
supplying a cleaning liquid to at least one surface of the substrate rotated at the first high rotational speed to clean the treatment liquid attached to the substrate; and
removing a chemical liquid attached to at least one of the substrate holding mechanism and the substrate rotation mechanism in a state such that the at least one surface of the substrate is covered with the cleaning liquid.

14. The substrate processing method as recited in claim 13, wherein the first high rotational speed is in a range of 1000 to 3000 rpm.

15. The substrate processing method as recited in claim 13, further comprising rotating the substrate at a second high rotational speed to remove the cleaning liquid and dry the substrate.

16. The substrate processing method as recited in claim 15, wherein said rotating the substrate at a second high rotational speed comprises rotating the substrate at a high rotational speed substantially equal to the first high rotational speed for a desired period of time.

17. A substrate processing method comprising:
holding a substrate by a substrate holding mechanism;
rotating the substrate holding mechanism by a substrate rotation mechanism to rotate the substrate;
supplying a treatment liquid to the rotating substrate to process the substrate; and
supplying a cleaning liquid to the rotating substrate to clean the substrate holding mechanism.

18. The substrate processing method as recited in claim 17, wherein said rotating the substrate holding mechanism comprises rotating the substrate holding mechanism at a rotational speed lower than 300 rpm during said supplying the cleaning liquid.

19. A substrate processing method comprising:
holding a substrate by a substrate holding mechanism;
rotating the substrate holding mechanism by a substrate rotation mechanism to rotate the substrate;
supplying a treatment liquid to the rotating substrate to process the substrate;
rotating the substrate at a first high rotational speed after supplying the treatment liquid;
supplying a cleaning liquid to at least one surface of the substrate rotated at the first high rotational speed to clean the treatment liquid attached to the substrate;
removing a chemical liquid attached to at least one of the substrate holding mechanism and the substrate rotation mechanism in a state such that the at least one surface of the substrate is covered with the cleaning liquid;
supplying a cleaning liquid to the rotating substrate to clean the substrate holding mechanism; and
rotating the substrate at a second rotational speed substantially equal to the first high rotational speed for a desired period of time to remove the cleaning liquid and dry the substrate.

20. The substrate processing method as recited in claim 13, wherein the cleaning liquid comprises pure water, deaerated water, or gas dissolved water.

21. The substrate processing method as recited in claim 9, wherein supplying the treatment liquid comprises supplying the treatment liquid to a peripheral portion of the substrate to remove a film formed on the peripheral portion of the substrate.

22. The substrate processing method as recited in claim 21, wherein the film to be removed comprises a film containing one of Cu, Co, Co alloy, Ta, Ta—N, W, W—N, Ti, Ti—N, Ni, Ru, P, B, and Mo, or a film having a plurality of layers each containing one of Cu, Co, Co alloy, Ta, Ta—N, W, W—N, Ti, Ti—N, Ni, Ru, P, B, and Mo.

23. A substrate processing method comprising:
holding a substrate by a substrate holding mechanism;
rotating the substrate holding mechanism by a substrate rotation mechanism to rotate the substrate;
supplying a treatment liquid to the rotating substrate to process the substrate;
supplying a chemical liquid from a first liquid supply nozzle to the substrate;
switching a liquid to be supplied from the first liquid supply nozzle into a cleaning liquid;
supplying the cleaning liquid to the substrate;
supplying a leaning liquid to the first liquid supply nozzle and vicinity of the first liquid supply nozzle to clean the first liquid supply nozzle and vicinity of the first liquid supply nozzle; and
rotating the substrate holding mechanism to remove a liquid attached to the substrate and dry the substrate; and
supplying a gas from a gas supply nozzle to a space between the substrate and a base member having the substrate holding mechanism attached thereon during said drying the substrate.

24. The substrate processing method as recited in claim 23, further comprising:
stopping said supplying the cleaning liquid; and
discharging a liquid remaining in the first liquid supply nozzle and a line connected to the first liquid supply nozzle after said stopping and before said drying the substrate.

25. The substrate processing method as recited in claim 23, further comprising:
supplying a cleaning liquid from a second liquid supply nozzle, before said drying the substrate, to clean an inner surface of the substrate holding mechanism and an upper surface of a base member having the substrate holding mechanism attached thereon.

26. (canceled)

27. The substrate processing method as recited in claim 23, further comprising:
supplying the gas from the gas supply nozzle to the space between the substrate and the base member during said cleaning the first liquid supply nozzle and the vicinity thereof.

28. The substrate processing method as recited in claim 13, wherein said removing the chemical liquid comprises removing a chemical liquid attached to a scatter prevention cup disposed so as to surround the substrate holding mechanism.

29. The substrate processing method as recited in claim 17, wherein said supplying the chemical liquid comprises removing a chemical liquid attached to a scatter prevention cup disposed so as to surround the substrate holding mechanism.

30. The substrate processing apparatus as recited in claim 3, further comprising a scatter prevention cup disposed outside of said substrate holding mechanism so as to cover said substrate holding mechanism, said scatter prevention cup being movable in a vertical direction.

31. The substrate processing method as recited claim 17, wherein the cleaning liquid comprises pure water, deaerated water, or gas dissolved water.

32. The substrate processing method as recited claim 19, wherein the cleaning liquid comprises pure water, deaerated water, or gas dissolved water.

33. The substrate processing method as recited claim 13, wherein supplying the treatment liquid comprises supplying the treatment liquid to a peripheral portion of the substrate to remove a film formed on the peripheral portion of the substrate.

34. The substrate processing method as recited claim 17, wherein supplying the treatment liquid comprises supplying the treatment liquid to a peripheral portion of the substrate to remove a film formed on the peripheral portion of the substrate.

35. The substrate processing method as recited in claim 19, wherein supplying the treatment liquid comprises supplying the treatment liquid to a peripheral portion of the substrate to remove a film formed on the peripheral portion of the substrate.
